(19) United States
(12) Patent Application Publication
(10) Pub. No.: US 2024/0242770 A1
(43) Pub. Date: Jul. 18, 2024

(54) NON-VOLATILE MEMORY DEVICE AND RECOVERY METHOD OF NON-VOLATILE MEMORY DEVICE

(71) Applicant: Samsung Electronics Co., Ltd., Suwon-si (KR)

(72) Inventors: Hojoon KIM, Suwon-si (KR); Jae-Duk YU, Suwon-si (KR); Yohan LEE, Suwon-si (KR); Jiho CHO, Suwon-si (KR)

(73) Assignee: Samsung Electronics Co., Ltd., Suwon-si (KR)

(21) Appl. No.: 18/400,049

(22) Filed: Dec. 29, 2023

(30) Foreign Application Priority Data
Jan. 17, 2023 (KR) 10-2023-0006955
May 12, 2023 (KR) 10-20230061931

(51) Int. Cl. G11C 16/34; G11C 16/04

(52) U.S. Cl. CPC G11C 16/3427; G11C 16/0483

(57) ABSTRACT

A non-volatile memory device according to some example embodiments includes a memory block including a plurality of cell strings including a plurality of string selection transistors and a plurality of memory cells, a first string selection line connected to a string selection transistor of a first cell string of the plurality of cell strings, and a second string selection line connected to a string selection transistor of a second cell string of the plurality of cell strings; and a control circuit configured to control a recovery operation to apply a recovery voltage with different driving strengths to the first string selection line and the second string selection line.

### CROSS-REFERENCE TO RELATED APPLICATION

This application claims priority to and the benefit of Korean Patent Application No. 10-2023-0006955 filed in the Korean Intellectual Property Office on Jan. 17, 2023, and Korean Patent Application No. 10-2023-0061931 filed in the Korean Intellectual Property Office on May 12, 2023, the entire contents of which are incorporated herein by reference.

### BACKGROUND

### (1) Field

The disclosure relates to non-volatile memory devices and recovery methods of the non-volatile memory devices.

### (2) Description of Related Art

A memory device is used to store data, and is classified into a volatile memory device and a non-volatile memory device. The non-volatile memory device can store data even when power is cut off. The non-volatile memory device is mainly used as a large capacity memory to store programs and data in a wide range of application devices such as computers and portable communication devices.

Recently, as the non-volatile memory device have increasingly higher density and larger capacity, various problems are occurring.

### SUMMARY

Some example embodiments provide non-volatile memory devices that can prevent or reduce a hot carrier injection (HCI) phenomenon, and recovery methods of the non-volatile memory devices.

Some example embodiments provide non-volatile memory devices that can prevent or reduce read disturb deterioration, and recovery methods of the non-volatile memory devices.

A non-volatile memory device according to some example embodiments to address these technical objects includes a memory block including a plurality of cell strings including a plurality of string selection transistors and a plurality of memory cells, a first string selection line connected to a string selection transistor of a first cell string of the plurality of cell strings, and a second string selection line connected to a string selection transistor of a second cell string of the plurality of cell strings; and a control circuit configured to control a recovery operation to apply a recovery voltage with different driving strengths to the first string selection line and the second string selection line.

Some example embodiments include a recovery method of a non-volatile memory device that includes a plurality of cell strings including a plurality of string selection transistors and a plurality of memory cells, includes applying a string selection turn-on voltage to a first string selection line connected to a string selection transistor of a first cell string of the plurality of cell strings, and applying a string selection turn-off voltage to a second string selection line connected to a string selection transistor of a second cell string of the plurality of cell strings; applying the string selection turn-on voltage to the first string selection line and the second string selection line; counting a period of a voltage of the first string selection line being less than or equal to a first reference voltage; and applying a recovery voltage with different drive strengths to the first string selection line and the second string selection line based on a time length of the period.

semiconductor device according to some example embodiments includes a substrate; a stacking structure that includes a plurality of first selection gate electrodes and a plurality of memory gate electrodes stacked at a distance from each other on the substrate; a first channel structure that penetrates the stacking structure and extends in a first direction; an insulation pattern on the stacking structure and covers the first channel structure; a conductive pattern that penetrates the insulation pattern and is connected with the first channel structure; a plurality of second selection gate electrodes on the conductive pattern; and a plurality of second channel structures that penetrate the plurality of second selection gate electrodes and extend in the first direction and thus widths of the plurality of second gate electrodes in a second direction that crosses the first direction are different from each other, wherein the plurality of second selection gate electrodes may be applied with a same voltage with different drive strengths.

### BRIEF DESCRIPTION OF THE DRAWINGS

FIG. 1 is a block diagram of a non-volatile memory device according to some example embodiments, and a memory system including the non-volatile memory device.

FIG. 2 is a block diagram of the non-volatile memory device according to some example embodiments.

FIG. 3 is a perspective view of an example of a memory block included in the memory cell array of the non-volatile memory device of FIG. 2.

FIG. 4 is a circuit diagram that shows an equivalent circuit of the memory block described with reference to FIG. 3.

FIG. 5 is a schematic top plan view of the memory block described with reference to FIG. 4.

FIG. 6 is an enlarged top plan view of the region A of FIG. 5.

FIG. 7 is a cross-sectional view of FIG. 5, taken along the line I-I′.

FIG. 8 is an enlarged view of the region B of FIG. 7.

FIG. 9 is a block diagram of a control circuit of a non-volatile memory device according to some example embodiments.

FIG. 10 is a block diagram of a voltage generator of a non-volatile memory device according to some example embodiments.

FIG. 11 is a block diagram of an address decoder of a non-volatile memory device according to some example embodiments.

FIG. 12 is a block diagram of a part of a non-volatile memory device according to some example embodiments.

FIG. 13 is a block diagram of a part of a non-volatile memory device according to some example embodiments.

FIG. 14 shows voltages of a string selection line, a word line, and a ground selection line in the recovery period after read.

FIG. 15 is a voltage potential graph of cell strings according to the voltages of FIG. 14.

FIG. 16 shows voltages of the string selection line, the word line, the channel, and the ground selection line in the recovery operation.

FIG. 17 is a block diagram of a voltage detector according to some example embodiments.

FIG. 18 shows the voltage change of the voltage detector signal, string selection line, and word line according to some example embodiments.

FIG. 19 is a block diagram of a voltage detector according to some example embodiments.

FIG. 20 shows the voltage change of the voltage detector signal, string selection line, word line, and ground selection line according to some example embodiments.

FIG. 21 is a flowchart of a recovery method according to some example embodiments.

FIG. 22 is a flowchart of a recovery method according to some example embodiments.

FIG. 23 is a block diagram of an example of application of the non-volatile memory device according to some example embodiments to a solid-state drive (SSD) system.

### DETAILED DESCRIPTION

In the following detailed description, only some example embodiments of the present inventions have been shown and described, simply by way of illustration. As those skilled in the art would realize, the described example embodiments may be modified in various different ways, all without departing from the spirit or scope of the present inventions.

Accordingly, the drawings and description are to be regarded as illustrative in nature and not restrictive. Like reference numerals designate like elements throughout the specification. In the flowchart described with reference to the drawing, the order of operations may be changed, several operations may be merged, a certain operation may be divided, and a specific operation may not be performed.

In addition, expressions described in the singular may be construed in the singular or plural unless an explicit expression such as “one” or “single” is used. The terms including ordinal numbers such as first, second, etc. may be used to describe various elements, but the elements are not limited by the terms. The terms are used only for the purpose of distinguishing one element from another element.

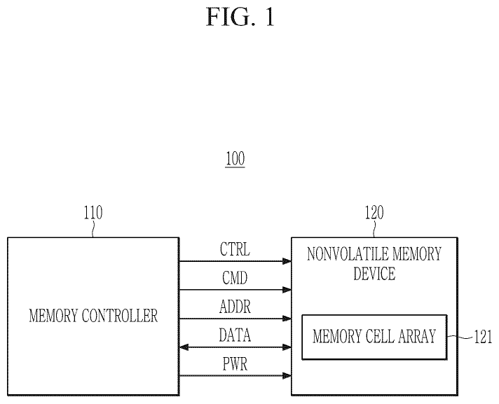

FIG. 1 is a block diagram of a non-volatile memory device according to some example embodiments, and a memory system including the non-volatile memory device.

Referring to FIG. 1, a memory system 100 may include a memory controller 110 and at least one memory device 120. The memory device 120 may be a non-volatile memory device, and the memory system 100 may include a flash memory-based data storage media such as a memory card, a USB memory, an SSD, and the like.

The non-volatile memory device 120 may perform erase, write, and/or read operations according to the control of the memory controller 110. For this purpose, the non-volatile memory device 120 receives a command CMD and an addresses ADDR from the memory controller 110 through input and output lines, and transmits and receives data DATA for program operation or read operation with the memory controller 110. In addition, the non-volatile memory device 120 may receive a control signal CTRL through a control line, and may receive power PWR from the memory controller 110.

The non-volatile memory device 120 may include a memory cell array 121. The memory cell array 121 may include a plurality of memory cells, and, for example, the plurality of memory cell may be flash memory cells. Hereinafter, example embodiments of the present disclosure will be described with a case in which the plurality of memory cells are NAND flash memory cells as an example. However, the technical concepts of the present disclosure are not limited thereto, and the plurality of memory cells may be various types of non-volatile memory cells. In some example embodiments, the plurality of memory cells may be resistive memory cells such as a resistive RAM (RRAM), a phase change RAM (PRAM), or a magnetic RAM (MRAM).

The memory cell array 121 may include a plurality of cell strings that share a bit line. Each of the plurality of cell strings may include a plurality of ground selection transistors connected to a plurality of ground selection lines, a plurality of memory cells connected to a plurality of word lines, and a plurality of string selection transistors connected to a plurality of string selection lines. The memory cell array 121 may be a two-dimensional 2D memory array. Alternatively, the memory cell array 121 may be a 3-dimensional 3D memory array.

The non-volatile memory device 120 may detect a voltage of the plurality of string selection lines, and may control the intensity of a recovery voltage applied to the plurality of string selection lines. In some example embodiments, the non-volatile memory device 120 may detect voltage changes of the plurality of string selection lines due to a difference in recovery (RC) delay of the plurality of string selection lines. The non-volatile memory device 120 may control the driving strength of the recovery voltage applied to the string selection line such that the intensity of the recovery voltage applied to string select lines with relatively slow voltage changes is greater than the intensity of the recovery voltage applied to string select lines with relatively fast voltage changes. According to some example embodiments, it is possible to prevent the HCI phenomenon in a cell string connected to a string selection line with a relatively slow voltage change, and to prevent read disturb degradation in a cell string connected to a string selection line with a relatively fast voltage change.

The non-volatile memory device 120 may detect a voltage of a plurality of ground selection lines, and may control application timing of the recovery voltage to a plurality of ground selection lines. A voltage of the plurality of ground selection lines may be boosted by capacitive coupling between the plurality of ground selection lines. The non-volatile memory device 120 may detect a voltage of the ground selection line of which the voltage is boosted, and may control application timing of the recovery voltage to the plurality of ground selection lines. In some example embodiments, the non-volatile memory device 120 may control application timing of the recovery voltage to the plurality of word lines and the plurality of string selection lines based on the detected voltage. According to some example embodiments, it is possible to prevent the HCI phenomenon in a cell string connected to a ground selection line with a relatively slow voltage change, and to prevent read disturb degradation in a ground string connected to a string selection line with a relatively fast voltage change.

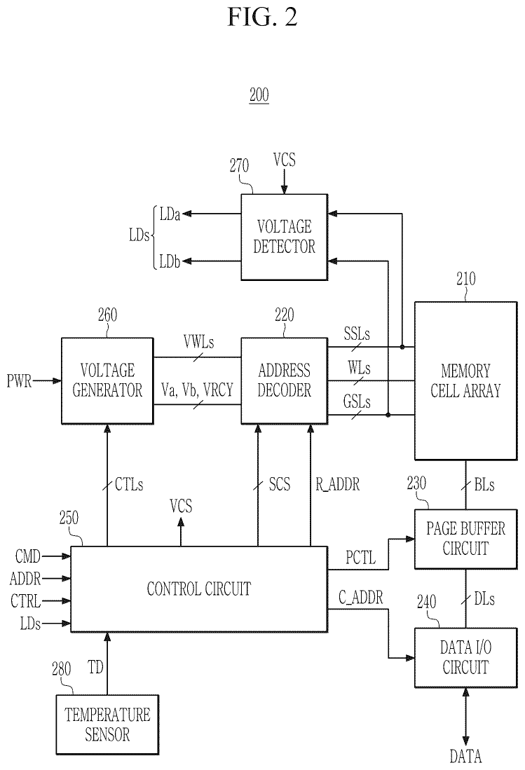

FIG. 2 is a block diagram of the non-volatile memory device according to some example embodiments.

The non-volatile memory device 200 may include a memory cell array 210, an address decoder 220, a page buffer circuit 230, data input and output (I/O) circuit 240, a control circuit 250, a voltage generator 260, a voltage detector 270, and a temperature sensor 280.

The memory cell array 210 may be connected with the address decoder 220 through a plurality of string selection lines SSLs, a plurality of word lines WL, and a plurality of ground selection lines GSL. In addition, the memory cell array 210 may be connected with the page buffer circuit 230 through the plurality of bit lines BL. The memory cell array 210 may include a plurality of non-volatile memory cells connected to the plurality of word lines WL and the plurality of bit lines BL.

In some example embodiments, the memory cell array 210 may be a three dimensional (3D) memory cell array formed in a three-dimensional structure (or vertical structure) on a substrate. In this case, the memory cell array 210 may include vertical cell strings including a plurality of memory cells stacked with each other.

The control circuit 250 may receive a command signal CMD and an address signal ADDR from the memory controller 50, and may control an erase loop, a program loop, and read operation of the non-volatile memory device 200. Here, the program loop may include a program operation and a program verify operation, and the erase loop may include an erase operation and an erase verify operation. Here, the read operation may include a normal read operation and a data recovery read operation.

For example, the control circuit 250 may generates a control signal CTLs for controlling the voltage generator 260, generate a page buffer control signal PCTLs for controlling the page buffer circuit 230, and generate a control signal VCS for controlling the voltage detector 270 based on the command signal CMD, and may generate a row address R_ADDR and a column address C_ADDR based on the address signal ADDR. The control circuit 250 may provide the row address R_ADDR to the address decoder 220, and may provide the column address C_ADDR to the data input and output circuit 240. In addition, the control circuit 250 may provide a switching control signal SCS to the address decoder 220 based on the command signal CMD.

The control circuit 250 may generate a control signal CTLs and/or switching control signal SCS based on the detection signal LDs. In some example embodiments, the control circuit 250 may generate, based on the first detection signal LDa, a control signal CTLs and/or switching control signal SCS that change the driving strength of the recovery voltage VRCY applied to the string selection lines SSLs. For example, when a circuit that controls the drive strength of the recovery voltage VRCY is included in the voltage generator 260, the control circuit 250 may generate control signals CTLs to change the drive strength of the recovery voltage VRCY. When a circuit that controls the drive strength of the recovery voltage VRCY, the control circuit 250 may change the drive strength of the recovery voltage VRCY through the switching control signal SCS. In some example embodiments, the control circuit 250 may generate, based on a second detection signal LDb, a switching control signal SCS to change application timing of the recovery voltage VRCY to the plurality of ground selection lines GSLs. In addition, the control circuit 250 may generate, based on the second detection signal LDb, a switching control signal SCS to change application timing of the recovery voltage VRCY to the string selection lines SSLs and the word lines WLs.

The control circuit 250 may generate a control signal VCS that controls the voltage detector 270 to change a first reference voltage for measuring the degree of voltage change of the plurality of string selection lines SSLs and/or a second reference voltage for measuring the voltage of the plurality of ground selection lines GSLs with reference to temperature information TD provided from the temperature sensor 280. For example, when the control circuit 250 determines that a temperature exceeds a first reference value from the temperature information TD, the control circuit 250 may set the first reference voltage and the second reference voltage as higher voltage. In some example embodiments, the control circuit 250 may generate a control signal VCS to control the voltage detector 270 to change the first reference voltage and/or second reference voltage for each operation mode (ERS, PGM, VFY, RD, IDR, or Reset). For example, the control circuit 250 may set a level of the first reference voltage set for the recovery operation in the easer mode and a level of the first reference voltage set for the recovery operation in the program mode to be different from each other.

The address decoder 220 may be connected with the memory cell array 210 through the plurality of string selection lines SSLs, the plurality of word lines WLs, and the plurality of ground selection lines GSLs.

In the program operation or read operation, the address decoder 220 may determine one or the plurality of word lines WLs as a selected word line based on the row address R_ADDR provided from the control circuit 250, and may determine the rest word lines as unselected word lines. The address decoder 220 may determine one of the plurality of string selection lines SSLs as a selected string selection line based on the switching control signal SCS provided from the control circuit 250, and may determine the rest string selection lines as unselected string selection lines. The address decoder 220 may adjust a floating point of the ground selection lines GSLs according to the switching control signal SCS during erase operation.

In some example embodiments, the address decoder 220 may control the drive strength of the recovery voltage VRCY applied to the string selection lines SSLs. The address decoder 220 may control application timing of the recovery voltage VRCY to the plurality of ground selection lines GSLs.

The voltage generator 260 may generate word line voltages VWLs, a string selection line voltage Va, ground selection line voltages Vb1 and Vb2, and a recovery voltage VRCY required for operation of the non-volatile memory device 200 with the power PWR based on the control signals CTLs provided from the control circuit 250. The word line voltages VWLs generated from the voltage generator 260 may be applied to the plurality of word lines WLs through the address decoder 220. The string selection line voltage Va generated from the voltage generator 260 may be applied to the plurality of string selection lines SSLs through the address decoder 220. The ground selection line voltages Vb1 and Vb2 generated from the voltage generator 260 may be applied to the plurality of ground selection lines GSLs through the address decoder 220. The recovery voltage VRCY generated from the voltage generator 260 may be applied to the plurality of string selection lines SSLs, the plurality of word lines WLs, and the plurality of ground selection lines GSLs through the address decoder 220.

In some example embodiments, the voltage generator 260 may control the drive strength of the recovery voltage VRCY applied to the string selection lines SSLs. The voltage generator 260 may control application timing of the recovery voltage VRCY to the plurality of ground selection lines GSLs.

The page buffer circuit 230 may be connected with the memory cell array 210 through the plurality of bit lines BL. The page buffer circuit 230 may include a plurality of page buffers. The page buffer circuit 230 may temporarily store data to be programmed in a selected page during a program operation, and may temporarily store data read from the selected page during a read operation.

The data input and output circuit 240 may be connected with the page buffer circuit 230 through the plurality of data lines DLs. In the program operation, the data input and output circuit 240 may receive program data DATA from the memory controller 100 (refer to FIG. 1), and may provide the program data DATA to the page buffer circuit 230 based on the column address C_ADDR provided from the control circuit 250. In the read operation, the data input and output circuit 240 may provide read data DATA stored in the page buffer circuit 230 based on the column address C_ADDR provided from the control circuit 250.

The voltage detector 270 may be connected with the plurality of string selection lines SSLs, and may output a first detection signal LDa that instructs the change degree of the voltage of the plurality of string selection lines SSLs. The voltage detector 270 may be connected with the plurality of ground selection lines GSLs, and may output a second detection signal LDb that instructs the voltage of the plurality of ground selection lines GSLs.

The temperature sensor 280 may provide temperature information TD of a sensed non-volatile memory device 200. The temperature sensor 280 may measure an internal temperature of the non-volatile memory device 200 to generate a numerical information-converted operating temperature TD. However, it will be well understood that the temperature measuring method of the temperature sensor 280 is not limited thereto and may be applied in various ways.

The voltage detector 270 may receive the control signal VCS from the control circuit 250. The voltage detector 270 may change the first reference voltage and/or second reference voltage based on the control signal VCS.

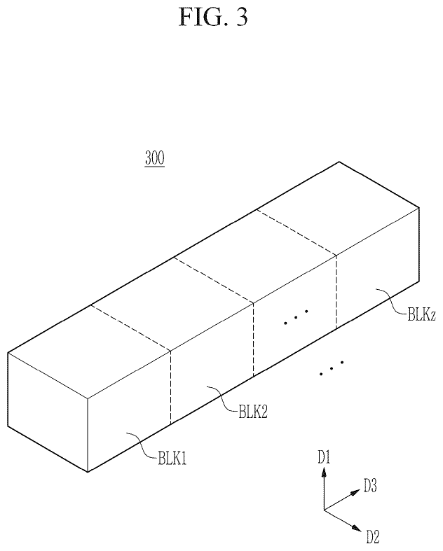

FIG. 3 is a perspective view of an example of a memory block included in the memory cell array of the non-volatile memory device of FIG. 2.

Referring to FIG. 3, the memory cell array 300 includes a plurality of memory blocks BLK1 to BLKz (here, z is a natural number greater than or equal to 3) arranged in a plurality of directions D1, D2, and D3. In some example embodiments, the memory blocks are selected by the address decoder 220 shown in FIG. 2. For example, the address decoder 1100 may select a memory block BLK corresponding to a block address among the memory blocks BLK1 to BLKz.

Hereinafter, a direction substantially perpendicular or perpendicular to the top surface of the substrate is defined as a first direction D1, and two directions that cross each other while being parallel with the top surface of the substrate are respectively defined as a second direction D2 and a third direction D3. For example, the second direction D2 and the third direction D3 may substantially perpendicularly or perpendicularly cross each other. The first direction D1 may also be referred to as a vertical direction, the second direction D2 as a row direction, and the third direction D3 as a column direction. The direction indicated by the arrow on the drawing and its opposite direction are explained as the same direction. The definition of the aforementioned direction is the same in all subsequent drawings.

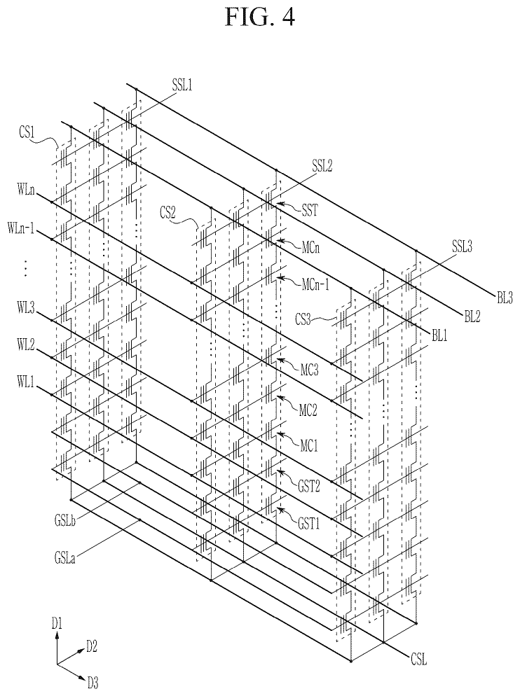

FIG. 4 is a circuit diagram that shows an equivalent circuit of the memory block described with reference to FIG. 3.

Referring to FIG. 4, the cell array of the 3-D semiconductor memory device may include a plurality of memory blocks. A memory block BLKi may include cell strings CS1, CS2, and CS3 that are two-dimensionally arranged along the second and third directions D2 and D3 and extend along the first direction D1. The cell strings CS1, CS2, and CS3 may be respectively coupled in parallel with bit lines BL1, BL2, and BL3. The two-dimensionally arranged cell strings CS1, CS2, and CS3 may be commonly connected to a common source line CSL.

Each of the cell strings CS1, CS2, and CS3 may include a plurality of memory cells MC1 to MCn coupled in series in the first direction D1, a plurality of ground selection transistors GST1 and GST2 coupled in series between the common source line CSL and the plurality of memory cells MC1 to MCn, and a string selection transistor SST connected between the plurality of memory cells MC1 to MCn and a corresponding bit line among the bit lines BL1, BL2, and BL3.

The memory cells MC1 to MCn may be respectively controlled by the plurality of word lines WL1 to WLn. Gate electrodes of the memory cells MC1 to MCn disposed in the same level from the common source line CSL may be commonly connected one of the word lines WL1 to WLn. In addition, each of the memory cells MC1 to MCn includes a data storage element.

The ground selection lines GSLa and GSLb and the string selection lines SSL1, SSL2, and SSL3 may be respectively separated from each other. Each of the cell strings CS1, CS2, and CS3 may include first and second ground selection transistors GST1 and GST2 that are coupled in series. The first and second ground selection transistors GST1 and GST2 may be controlled by lower and upper ground selection lines GSLa and GSLb. The first ground selection transistor GST1 may be connected to the lower ground selection line GSLa and the second ground selection transistor GST2 may be connected to the upper ground selection line GSLb. In each cell string CS, the first ground selection transistor GST1 and the second ground selection transistor GST2 may have different threshold voltages.

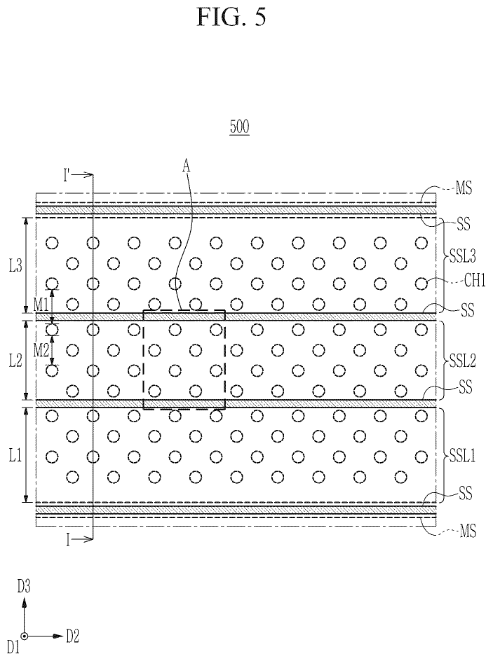

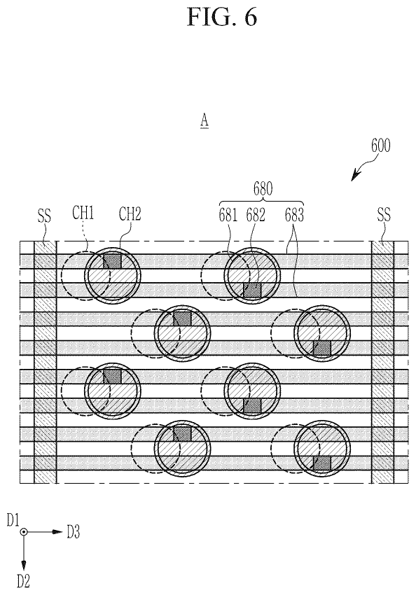

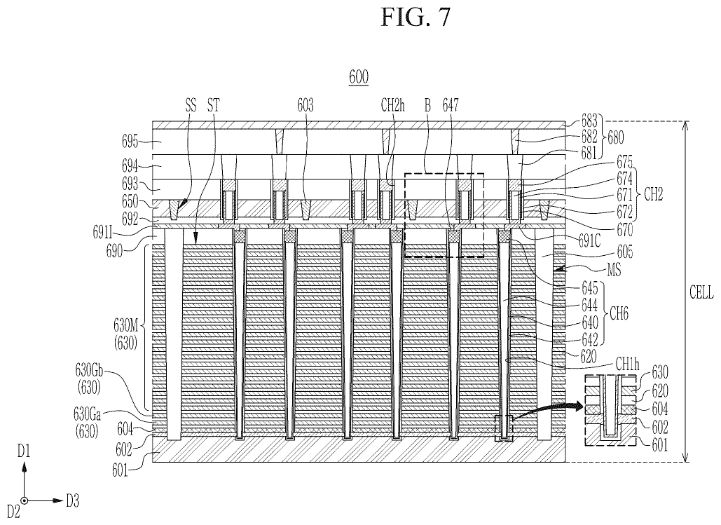

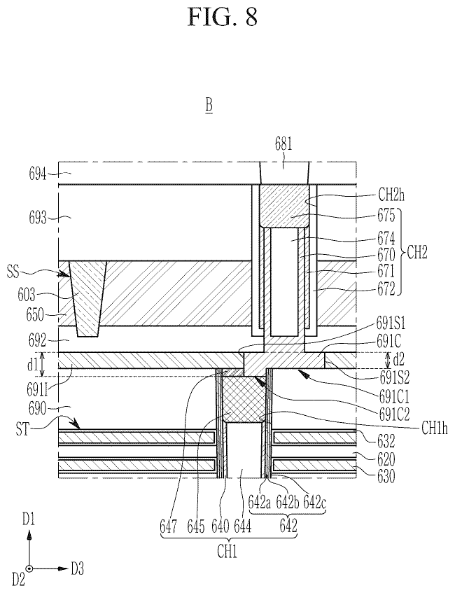

FIG. 5 is a schematic top plan view of the memory block described with reference to FIG. 4, FIG. 6 is an enlarged top plan view of the region A of FIG. 5, FIG. 7 is a cross-sectional view of FIG. 5, taken along the line I-I′, and FIG. 8 is an enlarged view of the region B of FIG. 7.

Referring to FIG. 5 to FIG. 8, a memory cell region CELL may include a substrate 601, first and second horizontal conductive layers 602 and 604 disposed on the substrate 601, a stacking structure ST formed of a first gate electrodes 630 and an interlayer insulation layers 620 that are alternately stacked, first channel structures CH1 penetrating the stacking structure ST, extending along the third direction (e.g., Z direction), and respectively including first channel layers 640, separation regions MS penetrating the stacking structure ST and extending along the third direction (Z direction), an insulation pattern 691I disposed on the separation regions MS with the first channel structures CH1, a second gate electrode 650 disposed on the insulation pattern 691I, second channel structures CH2 that penetrate the second gate electrode 650, extend along the third direction (Z direction), and respectively include second channel layers 670, and upper separation regions SS penetrating the second gate electrode 650 and extending along the third direction (Z direction).

The memory cell region CELL may further include a cell region insulation layer 690 disposed between the insulation pattern 691I and the stacking structure ST and covering the stacking structure ST, upper insulation layers 692, 693, 694, and 695 disposed on the cell region insulation layer 690, and an upper wire structure 680 connected with each of the second channel structures CH2.

As shown in FIG. 5, in the semiconductor device 500, a single cell string may be formed with each first channel structure CH1, and a plurality of cell strings may be arranged in rows and columns in the second direction (D2 direction) and the third direction (D3 direction).

The substrate 601 may have an upper plane extending in the second direction (D2 direction) and the third direction (D3 direction). The substrate 601 may include a semiconductor material, for example a group IV semiconductor, a group III-V compound semiconductor, or a group II-VI compound semiconductor. For example, the group-IV semiconductor may include silicon, germanium, or silicon-germanium. The substrate 601 may be provided as a bulk wafer, an epitaxial layer, a silicon-on-insulator (SOI) layer, a semiconductor-on-insulator (SeOI) layer, and the like. However, this is not restrictive.

The first and second horizontal conductive layers 602 and 604 may be stacked on the upper plane of the substrate 601. The first horizontal conductive layer 602 may serve as at least a part of a common source line of a semiconductor device 600, and for example, may serve as a common source line together with the substrate 601. The first horizontal conductive layer 602 may be directly connected with first channel layer 640 at a circumference of the first channel layer 640.

The first and second horizontal conductive layers 602 and 604 may include a semiconductor material, and for example, may include polysilicon. In this case, at least the first horizontal conductive layer 602 may be a layer doped with the same conductive type impurity as the substrate 601, and the second horizontal conductive layer 604 may be a doped layer or a layer containing impurity diffused from the first horizontal conductive layer 602. However, the material of the second horizontal conductive layer 604 is not limited to the semiconductor material, and in some example embodiments, the second horizontal conductive layer 604 may be replaced with an insulation layer.

The first gate electrodes 630 is separated on the substrate 601 in the first direction (D1 direction) and thus may form the stacking structure ST. The first gate electrodes 630 may include a first lower gate electrode 630Ga forming a gate of the first ground selection transistor, a second lower gate electrode 630Gb forming a gate of the second ground selection transistor, and memory gate electrodes 630M forming a plurality of memory cells. The number of memory gate electrodes 630M forming the memory cells may be determined according to the capacity of the semiconductor device 600. For example, the lower gate electrodes 630G may have a structure that is the same as or different from that of the memory gate electrodes 630M.

In some example embodiments, the first gate electrodes 630 may further include a gate electrode that forms an erase transistor that is disposed in a lower portion of the first lower gate electrode 630Ga and used in erase operation using a gate induced drain leakage (GILD) phenomenon. In addition, some of the first gate electrodes 630, for example, memory gate electrodes 630M adjacent to the second lower gate electrode 630Gb may be dummy gate electrodes.

The first gate electrodes 630 may contain a metal material, for example, tungsten (W). However, this is not restrictive, and in some example embodiments, the first gate electrodes 630 may include polysilicon or a metal silicide material.

In addition, in some example embodiments, the first gate electrodes 630 may further include a diffusion barrier (not shown), and for example, the diffusion barrier may contain tungsten nitride (WN), tantalum nitride (TaN), titanium nitride (TiN), or a combination thereof.

The interlayer insulation layers 620 may be disposed between the first gate electrodes 630, and may be alternately disposed with the first gate electrodes 630 in the first direction (D1 direction). Like the first gate electrodes 630, the interlayer insulation layers 620 may also be disposed to be spaced apart from each other in the first direction (D1 direction) on the upper plane of the substrate 601. The interlayer insulation layers 620 may include an insulating material such as silicon oxide or silicon nitride. However, this is not restrictive.

The first channel structures CH1 may be disposed apart from each other in rows and columns on the substrate 601, while each forming a single cell string. The first channel structures CH1 may be disposed to form a lattice pattern or disposed in a zigzag form in one direction on a plane where the second direction (D2 direction) and the third direction (D3 direction) cross each other. For example, the first channel structures CH1 may be disposed in a zigzag form by six channel structures arranged in a first column and six channel structures arranged in a second column between adjacent separation regions MS, but are not limited thereto, and the arrangement of the first channel structures CH1 may be changed in various ways.

Among the first channel structures CH1, two first channel structures CH1 that are disposed while forming a column in the third direction D3 and adjacent to each other may be respectively disposed in string selection lines SSL2 and SSL3 separated by the upper separation region SS. The shortest distance between the two first channel structures CH1 positioned on the string selection lines SSL2 and SSL3 separated from each other may be a first separation distance M1. Among the first channel structures CH1, two first channel structures CH1 disposed in a row in the third direction D3 and adjacent to each other may be positioned on the same string selection line SSL2. The shortest distance between two first channel structures CH1 positioned on the same string selection line SSL2 may be a second separation distance M2. The first separation distance M1 may be equal to or greater than the second separation distance M2.

The first channel structures CH1 may be provided in first channel holes CH1h that penetrate the stacking structure ST. Each of the first channel structure CH1s has a column shape and may have an inclined surface that becomes narrower closer to the substrate 601 according to an aspect ratio.

Each of the first channel structures CH1 may further include a first dielectric layer 642, a first fill insulation layer 644 between the first channel layers 640, and a first channel pad 645 at an upper end of the first fill insulation layer 644 in addition to the first channel layer 640.

The first channel layer 640 may be formed in an annular shape surrounding a first fill insulation layer 644 inside, but is not limited thereto, and in some example embodiments, may have a column shape such as a cylinder or a prism without the first fill insulation layer 644.

The first channel layer 640 may be connected to the first horizontal conductive layer 602 at the bottom. The first channel layer 640 may include a semiconductor material such as polysilicon, and the semiconductor material may be an undoped material or a material including a p-type or n-type impurity.

The first dielectric layer 642 may be disposed between the first gate electrodes 630 and the first channel layer 640.

Referring to FIG. 8, the first dielectric layer 642 may include a tunneling layer 642a, a charge storage layer 642b, and a blocking layer 642c that are sequentially stacked from the first channel layer 640.

The tunneling layer 642a may tunnel charge into the charge storage layer 642b, and may include, for example, a silicon oxide (SiO₂), a silicon nitride (Si₃N₄), a silicon oxynitride (SiOₓN_{y}), or a combination thereof. However, it is not limited thereto.

The charge storage layer 642b may be a charge trap layer or a floating gate conductive layer. The blocking layer 642c may include a silicon oxide (SiO₂), a silicon nitride (Si₃N₄), a silicon oxynitride (SiOₓN_{y}), a high-k material or a combination thereof.

In some example embodiments, the semiconductor device 600 may further include a gate dielectric layer 632 disposed between the first gate electrodes 630 and the interlayer insulation layers 620 and between the first gate electrodes 630 and the first channel structures CH1. The gate dielectric layer 632 may prevent or reduce charges in the charge storage layer 642b from moving to the first gate electrodes 630 together with the blocking layer 642c.

The first channel pad 645 may be disposed to cover an upper surface of the first fill insulation layer 644 and be electrically connected with the first channel layer 640. The first channel pad 645 may be disposed above the first channel layer 640. The first channel pad 645 may include, for example, polysilicon.

The separation region MS may penetrate stacking structure ST formed of the cell region insulation layer 690, the first gate electrodes 630, and the interlayer insulation layers 620, and the first and second horizontal conductive layers 602 and 604, and may be connected with the substrate 601 by extending in the first direction (D1 direction).

As shown in FIG. 5, the separation regions MS may be spaced apart from each other and disposed in parallel along the third direction (D3 direction). The separation region MSs may separate the first gate electrodes 630 from each other in the third direction (D3 direction).

The separation regions MS may have a shape of which a width decreases toward the substrate 601 due to a high aspect ratio. A separation insulation layer 605 may be disposed in the separation regions MS. The separation insulation layer 605 may include at least one of a silicon oxide, a silicon nitride, or a silicon oxynitride. However, this is not restrictive, and in some example embodiments, a conductive material layer may be disposed in the separation regions MS.

The cell region insulation layer 690 may cover the stacking structure ST formed of the first gate electrodes 630 and the interlayer insulation layers 620. The cell region insulation layer 690 may cover at least a part of side surfaces of the separation regions MS and/or first channel structures CH1, for example, portions extending upward from the stacking structure ST.

In some example embodiments, an upper surface of the cell region insulation layer 690 may be disposed in the substantially same or the same level as an upper surface of each of the first channel structures CH1, and the upper surface of the cell region insulation layer 690 may be disposed substantially in the same level or in the same as the upper surface of each of the separation regions MS.

The cell region insulation layer 690 may include at least one of a silicon oxide, a silicon nitride, or a silicon oxynitride. However, it is not limited thereto.

The insulation pattern 691I may be disposed on the first channel structures CH1 and the separation regions MS. The insulation pattern 691I may be positioned at a higher level than the stacking structure ST and the cell region insulation layer 690. The insulation pattern 691I may be disposed to have a conformal thickness and extend in the second direction (D2 direction) and third direction (D3 direction).

A thickness of the insulation pattern 691I may be substantially equal or equal to or smaller than a thickness of the first gate electrode 630.

The semiconductor device 600 may further include a conductive pattern 691C. The conductive pattern 691C may penetrate the insulation pattern 691I and thus may be connected with the first channel structures CH1.

The conductive pattern 691C may be a structure filled in a plurality of holes having a shape such as a circle, an ellipse, or a polygon. In the vertical first direction (D1 direction), the conductive pattern 691C may partially overlap with the first channel structures CH1.

The conductive pattern 691C may include a first side surface 691S1 that contacts the insulation pattern 691I on the first channel structure CH1, and a second side surface 691S2 that contacts the insulation pattern 691I on the cell region insulation layer 690.

A length d1 of the first side surface 691S1 in the first direction (D1 direction) may be longer than a length d2 of second side surface 691S2 in the first direction (D1 direction), but it is not limited thereto.

Some region of each of the first channel structures CH1 may overlap the conductive pattern 691C, and the remaining regions may overlap the insulation pattern 691I. That is, on a plane, a center of the conductive pattern 691C may be spaced apart from a center of each of the first channel structures CH1 in the third direction (D3 direction).

The conductive pattern 691C may include a semiconductor material such as silicon (Si), germanium (Ge), or a mixture thereof.

Each of the first channel structures CH1 may further include a capping pad 647. The capping pad 647 may be disposed between the insulation pattern 691I and the first channel pad 645. An upper surface of capping pad 647 may be disposed at substantially the same or the same level as an upper surface of cell region insulation layer 690, and may be disposed at substantially the same or the same level as a bottom plane of insulation pattern 691I.

The capping pad 647 may have a thinner thickness than the insulation pattern 691I. The capping pad 647 may include a material different from that of the insulation pattern 691I. The capping pad 647 may include a material having etching selectivity with respect to the insulation pattern 691I. For example, the capping pad 647 may include an oxide-based material such as silicon oxide. However, it is not limited thereto, and the material included in the capping pad 647 may be variously changed.

The capping pad 647 may be formed to prevent or reduce defects due to etching of the first channel pad 645 occurring in a forming process of the conductive pattern 691C, which will be described later. The conductive pattern 691C penetrates the capping pad 647 in a region overlapping with the first channel structure CH1 and may be in contact with the first channel pad 645.

However, in some example embodiments, the capping pad 647 may be omitted. In this case, an upper surface of the first channel pad 645 may be disposed at substantially the same or the same level as the upper surface of the cell region insulation layer 690 and may come into contact with the bottom plane of the insulation pattern 691I.

The conductive pattern 691C may include a first conductive pattern portion 691C1 on the cell region insulation layer 690 and a second conductive pattern portion 691C2 on the first channel pad 645.

A bottom surface of the first conductive pattern portion 691C1 is in contact with the cell region insulation layer 690, and a bottom surface of the second conductive pattern portion 691C2 may be in contact with the first channel pad 645. That is, a first side surface 691S1 of the conductive pattern 691C may be connected with the second conductive pattern portion 691C, and a second side surface 691S2 may be connected with the first conductive pattern portion 691C1.

In addition, some region of the first side surface 691S1 may contact a side surface of the insulation pattern 691I disposed at one side of the conductive pattern 691C in the third direction (D3 direction), and the remaining regions of the first side surface 691S1 may contact a side surface of the capping pad 647.

The second side surface 691S2 may wholly contact the side surface of the insulation pattern 691I positioned on the other side of the third direction (D3 direction) of the conductive pattern 691C.

Accordingly, the bottom surface of the second conductive pattern portion 691C2 may be disposed at a lower level than the bottom surface of the first conductive pattern portion 691C1. That is, the conductive pattern 691C may have a relatively thin thickness in the first conductive pattern portion 691C1, and may have a relatively thick thickness in the second conductive pattern portion 691C2.

The upper surface of the insulation pattern 691I may be disposed at the same level as the upper surface of the conductive pattern 691C, the bottom surface of the insulation pattern 691I may be disposed at the same level as the bottom surface of the first conductive pattern portion 691C1 and at a higher level than the bottom surface of the second conductive pattern portion 691C2. That is, the bottom surface of the insulation pattern 691I may be disposed at the same level as the upper surface of the cell region insulation layer 690, contacting the bottom surface of the first conductive pattern portion 691C1.

The second gate electrode 650 may be disposed on the insulation pattern 691I and the conductive pattern 691C. That is, the second gate electrode 650 may be disposed at a higher level than the first channel structures CH1.

A first upper insulation layer 692 may be disposed between the second gate electrode 650 and the insulation pattern 691I, and between the second gate electrode 650 and the conductive pattern 691C. The second gate electrode 650 may be disposed apart from the insulation pattern 691I by the first upper insulation layer 692.

The first upper insulation layer 692 may have a thicker thickness than the insulation pattern 691I. The first upper insulation layer 692 may include, for example, silicon oxide. A thickness of the second gate electrode 650 may be thicker than that of each of the first gate electrodes 630.

In addition, in some example embodiments, the second gate electrode 650 may include a material different from those of the first gate electrodes 630. For example, the second gate electrode 650 may be a semiconductor material layer such as polysilicon. However, in contrast, the second gate electrode 650 may include at least one of a doped semiconductor material, a metal (e.g., TiN, TaN), and a transition metal (e.g., Ti, Ta).

The second to fourth upper insulation layers 692, 693, and 694 may be sequentially stacked on the second gate electrode 650. The second to fourth upper insulation layers 692, 693, and 694 may include at least one of a silicon oxide, a silicon nitride, and a silicon oxynitride.

As shown in FIG. 5, the upper separation regions SS may be spaced apart from each other and disposed in parallel along the third direction (D3 direction). The upper separation regions SS may separate the second gate electrodes 650 from each other in the third direction (D3 direction). The second gate electrodes 650 separated by the upper separation regions SS may be string selection lines SSL1, SSL2, and SSL3 that form the string selection transistor SST (refer to FIG. 4).

Widths of the string selection lines SSL1, SSL2, and SSL3 may be a first length L1, a second length L2, and a third length L3, which are different from each other. Accordingly, resistance values R of the string selection lines SSL1, SSL2, and SSL3 may be different from each other. Hereinafter, it is assumed that the first length L1 and the third length L3 are substantially the same or the same, and the resistance values R of the string selection lines SSL1, and SSL3 are substantially the same or the same. Assuming that the capacity values C of the string selection lines SSL1, SSL2, and SSL3 are the same, the RC (resistance and capacity) value of the string selection line SSL2 is greater than the RC values of the string selection lines SSL1 and SSL3.

The upper separation regions SS may penetrate the second gate electrode 650 and may be disposed while extending in the second direction (D2 direction).

An upper surface of the upper separation regions SS may be disposed at substantially the same or the same level as the upper surface of the second gate electrode 650. The upper separation regions SS may penetrate the second gate electrode 650 and may extend into the first upper insulation layer 692. A bottom surface of the upper separation regions SS may be disposed at a higher level than the insulation pattern 691I.

The upper separation regions SS may be disposed at a higher level than separation regions MS. On a plane, at least some of the upper separation regions SS may overlap the separation regions MS extending along the second direction (D2 direction).

A distance between the adjacent separation regions MS in the third direction (D3 direction) may be greater than a distance between adjacent upper separation regions SS in the third direction (D3 direction). Accordingly, on a plane, at least some of the upper separation regions SS may be disposed between adjacent separation regions MS.

Since the upper separation regions SS and the second gate electrode 650 are disposed higher than the separation regions MS and the first channel structures CH1, the semiconductor device 600 of which the dummy structures between the first channel structures CH1 are omitted and thereby, the semiconductor device 600 may have improved integration.

An upper separation insulation layer 603 may be disposed inside the upper separation regions SS. The upper separation insulation layer 603 may include an insulating material such as a silicon oxide and the like. However, it is not limited thereto, and in some example embodiments, the upper separation regions SS may include at least some of materials of second channel structures CH2 described later.

Each of the second channel structures CH2 may be provided in a second channel hole CH2h penetrating the second gate electrode 650 and the second upper insulation layer 693.

An inner surface of the second channel hole CH2h may be defined by a first upper insulation layer 692, a second gate electrode 650, and a second upper insulation layer 693.

Specifically, a bottom surface of the second channel hole CH2h may be defined by the first upper insulation layer 692. That is, the bottom surface of the second channel hole CH2h may be disposed at a lower level than the bottom surface of the second gate electrode 650. Each of the second channel structure CH2 may extend below the bottom surface of the second channel hole CH2h and contact the upper surface of the conductive pattern 691C. An upper surface of each of the second channel structures CH2 may be covered by a third upper insulation layer 694.

Each of the second channel structures CH2 may be electrically connected to each of the first channel structures CH1 through the conductive pattern 691C. The second channel structures CH2 may be a string selection channel structure of the string selection transistor SST (refer to FIG. 4).

Each of the second channel structures CH2 may have a column shape. Unlike the first channel structures CH1 described above, the second channel structures CH2 may have a constant width. That is, a width of the upper surface and a width of the bottom surface of each of the second channel structures CH2 may be the same. However, it is not limited thereto, and in some example embodiments, like the first channel structures CH1, the second channel structures CH2 may have an inclined side surface that becomes narrower closer to the substrate 601 according to an aspect ratio.

The second channel structures CH2 may be spaced apart from each other and disposed while forming rows and columns on the insulation pattern 691I and the conductive pattern 691C. The second channel structures CH2 may be disposed to form a lattice pattern on a plane where the second direction (D2 direction) and the third direction (D3 direction) cross each other or disposed in a zigzag form in one direction.

Each of the second channel structures CH2 may further include a second dielectric layer 672, a second fill insulation layer 674 disposed between the second channel layers 670, a semiconductor spacer layer 671, and a second channel pad 675 disposed at an upper end of the second fill insulation layer 674, in addition to the second channel layer 670.

The second channel layer 670 may be formed in an annular shape surrounding the second fill insulation layer 674 therein. However, this is not restrictive, and in some example embodiments, the second channel layer 670 may have a column shape such as a cylinder or a prism without the second fill insulation layer 674. The second channel layer 670 may be connected to the conductive pattern 691C at the bottom. The second channel layer 670 may include a semiconductor material such as polysilicon, and the semiconductor material may be an undoped material or a material including a p-type or n-type impurity.

The second dielectric layer 672 may be disposed between the second gate electrode 650 and the second channel layer 670. In some example embodiments, the second dielectric layer 672 may include a different structure or different material from that of the first dielectric layer 642. For example, the first dielectric layer 642 may have a multi-layered structure, and the second dielectric layer 672 may have a single-layered structure. The second dielectric layer 672 may include a silicon oxide, a silicon nitride, a silicon oxynitride, or a high-k material.

The semiconductor spacer layer 671 may be a layer covering a part of an outer surface of the second channel layer 670. The semiconductor spacer layer 671 may have a conformal thickness, and may be disposed between the second dielectric layer 672 and the second channel layer 670. A lower end of the semiconductor spacer layer 671 may be disposed at a higher level than the insulation pattern 691I, and the second dielectric layer 672 may contact a part of a side surface of the second channel layer 670 while covering the lower end of the semiconductor spacer layer 671.

The lower end of the semiconductor spacer layer 671 may be disposed at a lower level than the bottom surface of the second gate electrode 650, but this is not restrictive, and in some example embodiments, the lower end of the semiconductor spacer layer 671 may be disposed substantially at the same level or at the same as the bottom surface of the second gate electrode 650.

The semiconductor spacer layer 671 may be a spacer structure for an anisotropic etching process to form the conductive pattern 691C, and may serve as a channel layer together with the second channel layer 670. The semiconductor spacer layer 671 may include a semiconductor material such as silicon and the like. For example, when the semiconductor spacer layer 671 and the second channel layer 670 include the same material, an interface between the two components may not be distinguished. However, in some example embodiments, the semiconductor spacer layer 671 may be omitted or may be replaced with a separate spacer layer other than a semiconductor.

In addition, the second channel layer 670 may extend in the third direction (Z direction) from the inside of the second channel hole CH2h, thereby contacting the first upper insulation layer 692.

The second channel layer 670 may be connected to the conductive pattern 691C to form an integral body. The second channel layer 670 and the conductive pattern 691C may be formed together, and no interface may exist between the second channel layer 670 and the conductive pattern 691C. However, this is not restrictive, and in some example embodiments, the second channel layer 670 and the conductive pattern 691C may be formed by a separate process, and when the second channel layer 670 and the conductive pattern 691C are formed by a separate process, an interface may be formed between the second channel layer 670 and the conductive pattern 691C.

The second channel pad 675 may cover an upper surface of the second fill insulation layer 674, and may be disposed to be electrically connected with the second channel layer 670. The second channel pad 675 may be disposed above the second channel layer 670. The second channel pad 675 may include, for example, polysilicon.

Referring to FIG. 6, a width of each of the second channel structures CH2 may be greater than a width of each of the first channel structures CH1. That is, a planar area of each of the second channel structures CH2 may be greater than a planar area of each of the first channel structures CH1.

In addition, the first channel structures CH1 and the second channel structures CH2 may be arranged to cross each other in the third direction (D3 direction). At least a part of the second channel structures CH2 may include a portion that does not overlap the first channel structures CH1 in the first direction (D1 direction). That is, at least a part of the first channel structures CH1 may include a first area overlapping the second channel structures CH2 in the first direction (D1 direction), and the remaining second area.

That is, since the first channel structures CH1 and the second channel structures CH2 are arranged to cross each other in the third direction (D3 direction), a central axis of each of the first channel structures CH1 and a central axis of each of the second channel structures CH2 may be arranged to cross each other in the first direction (D1 direction).

The upper wire structure 680 may include a conductive material, and may be electrically connected with the first and second channel structures CH1 and CH2. The upper wire structure 680 may include studs 681, contact plugs 682, and upper wire 683. The studs 681 may penetrate the third upper insulation layer 694 and contact the upper surface of each of the second channel structures CH2.

In FIG. 6, the planar area of each stud 681 is shown to be smaller than the planar area of each second channel structure CH2. However, this is for illustrative purposes of the studs 681, and the planar area of each stud 681 may be substantially the same or the same or smaller than the planar area of each second channel structure CH2.

The contact plugs 682 may penetrate a fourth upper insulation layer 695 to be connected with the studs 681. The upper wire 683 may be disposed on the contact plugs 682 and the fourth upper insulation layer 695. A part of the upper wire 683 may be bit lines (BL1, BL2, and BL3 of FIG. 4) that contact the contact plugs 682. As shown in FIG. 5 and FIG. 6, the bit lines may extend in the third direction (D3 direction) that crosses the second direction (D2 direction) in which the upper separation regions SS extend. The bit lines may be electrically connected with the second channel structures CH2 through the contact plugs 682.

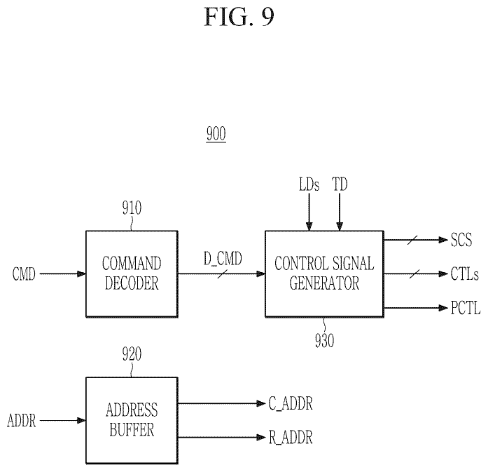

FIG. 9 is a block diagram of a control circuit of a non-volatile memory device according to some example embodiments.

Referring to FIG. 9, a control circuit 900 may include a command decoder 910, an address buffer 920, and a control signal generator 930.

The command decoder 910 may decode a command signal CMD to provide a decoded command D_CMD to a control signal generator 930.

The address buffer 920 may receive an address signal ADDR, and may provide a row address R_ADDR of the address signal ADDR to the address decoder (for example, the non-volatile memory device 200 of FIG. 2) and provide a column address C_ADDR to the data input and output circuit (for example, the data input and output circuit 240 of FIG. 2).

The control signal generator 930 may receive the decoded command D_CMD, generate control signal CTLs based on the operation indicated by the decoded command D_CMD, provide the control signals CTLs to the voltage generator (for example, the voltage generator 260 of FIG. 2), generate page buffer control signals PCTL, and provide the page buffer control signal PCTL to the page buffer circuit (for example, the page buffer circuit 230 of FIG. 2). The control signal generator 920 may generate a switching control signal SCS based on the decoded command D_CMD and provide the switching control signal SCS to the address decoder 220.

In some example embodiments, the control signal generator 930 may generate control signals CTLs based on detection signals LDs, provide the control signals CTLs to the voltage generator (for example, the voltage generator 260 of FIG. 2), or generate a switching control signal SCS based on the detection signals LDs and provide the switching control signal SCS to the address decoder 220. The control signal generator 930 may generate a control signal VCS based on temperature information TD, and provide the control signal VCS to the voltage detector (for example, the voltage detector 270 of FIG. 2).

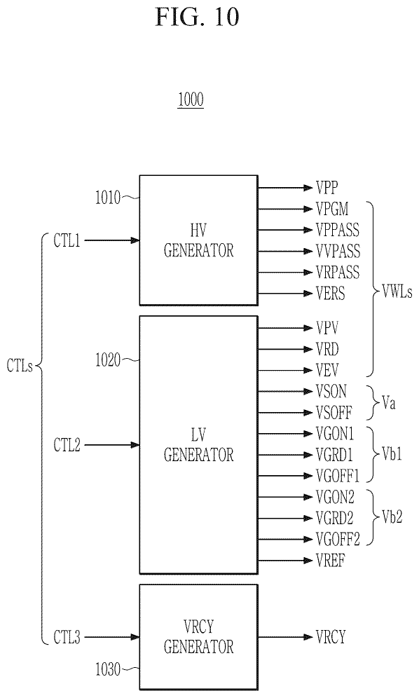

FIG. 10 is a block diagram of a voltage generator of a non-volatile memory device according to some example embodiments.

Referring to FIG. 10, a voltage generator 1000 may include a high voltage (HV) generator 1010 and a low voltage (LV) generator 1020. In some example embodiments, the voltage generator 1000 may further include a recovery voltage (VRCY) generator 1030.

The high voltage generator 1010 may generate a high voltage VPP, a program voltage VPGM, a program pass voltage VPPASS, a verifying pass voltage VVPASS, a read pass voltage VRPASS, and an erase voltage VERS according to the operation indicated by a command CMD in response to a first control signal CTL1.

The high voltage VPP may be applied to an address decoder (for example, the address decoder 220 of FIG. 2). The program voltage VPGM may be applied to a selection word line, the program pass voltage VPPASS, the program verifying pass voltage VVPASS, and the read pass voltage VRPASS may be applied to non-selection word line, and the erase voltage VERS may be applied to a well of a memory block. The first control signal CTL1 includes a plurality of bits, and may indicate the operation indicated by decoded command D_CMD.

In response to the second control signal CTL2, the low voltage generator 1020 may generate a program verifying voltage VPV, a read voltage VRD, an erase verifying voltage VEV, string selection voltages Va, ground selection voltages Vb1 and Vb2, and a reference voltage VREF according to the operation instructed by the command CMD.

The program verifying voltage VPV, the read voltage VRD, and the erase verifying voltage VEV may be applied to the selection word line according to an operation. A string selection turn-on voltage VSON and a string selection turn-off voltage VSOFF may be respectively applied to a string selection transistor of a selection cell string and a string selection transistor of a non-selection cell string. Ground selection turn-on voltages VGON1 and VGON2, ground selection read voltages VGRD1 and VGRD2, and ground selection turn-off voltages VGOFF1 and VGOFF2 may be ground selection transistors of the cell strings. The reference voltage VREF may be provided to a voltage detector (for example, the voltage detector 270 of FIG. 2). The second control signal CTL2 includes a plurality of bits, and may indicate the operation instructed by the decoded command D_CMD. In the above, the “turn-on” voltage, “read” voltage, and “turn-off” voltage are mentioned only to distinguish the levels of voltages, and do not refer to the intensity of the voltage levels that turn on, read, or turn off the transistor according to their names, and this is the same in the following description.

The recovery voltage generator 1030 may generate a recovery voltage VRCY according to the operation instructed by the command CMD in response to a third control signal CTL3. The third control signal CTL3 includes a plurality of bits, and may indicate the operation instructed by the decoded command D_CMD. The recovery voltage VRCY may be applied to word lines, string selection lines, and ground selection lines in a recovery period.

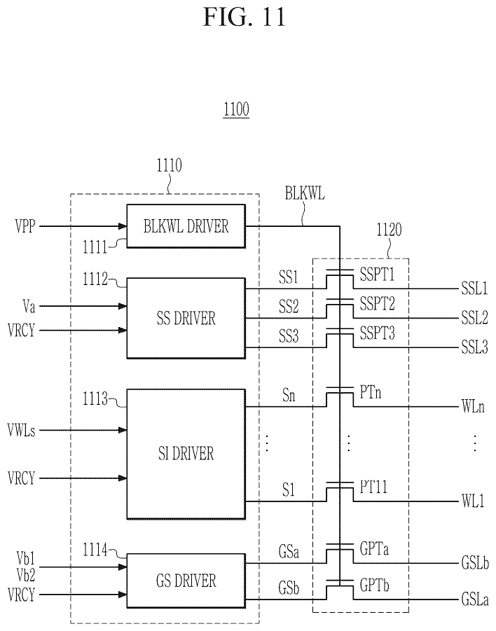

FIG. 11 is a block diagram of an address decoder of a non-volatile memory device according to some example embodiments.

Referring to FIG. 11, an address decoder 1100 may include a driver circuit 1110 and a pass switch circuit 1120.

The driver circuit 1110 provide voltages provided from a voltage generator (for example, the voltage generator 1000 of FIG. 10) to a memory cell array (for example, the memory cell array 210 of FIG. 2) in response to a block address. The driver circuit 1110 may include a block selection (BLKWL) driver 1111, a string selection (SS) driver 1112, a word line (SI) driver 1113, and a ground selection (GS) driver 1114.

The block selection driver 1111 may provide a high voltage VPP provided from the voltage generator 1000 to a pass transistor circuit 360 responding to the block address. The block selection driver 1111 may provide the high voltage to a block word line BLKWL connected to gates of a plurality of pass transistors GPTa, GPTb, PT1, . . . , PTn, SSPT1, SSPT2, and SSPT3 included in a pass switch circuit 1120. The block selection driver 1111 may control timing at which word line voltages VWLs, a string selection line voltage Va, ground selection line voltages Vb1 and Vb2, and a recovery voltage VRCY are applied.

The string selection driver 1112 may provide the string selection line voltage Va provided from the voltage generator 1000 to a string selection signal. For example, the string selection driver 1112 may provide a string selection turn-on voltage VSON to a selected string selection line of the string selection lines SSL1, SSL2, and SSL3 and provide a string selection turn-off voltage VSOFF to an unselected string selection line. In some example embodiments, the string selection driver 1112 may provide the recovery voltage VRCY provided from the voltage generator 1000 to the string selection lines SSL1, SSL2, and SSL3. The string selection driver 1112 may apply the recovery voltage VRCY with different drive strengths to the string selection lines SSL1, SSL2, and SSL3. For example, the string selection driver 1112 may apply the recovery voltage VRCY such that the drive strength for applying the recovery voltage VRCY to the string selection line SSL2 is greater than the drive strength for applying the recovery voltage VRCY to the string selection lines SSL1 and SSL3.

A driving line driver 1113 may provide the word line voltages VWLs and the recovery voltage VRCY provided from the voltage generator 1000 to word lines WL1 to WLn through driving lines S1 to Sn and pass transistors PT1 to PTn during program operation.

The ground selection driver 1114 may provide ground selection line voltages Vb1 and Vb2 and recovery voltage VRCY to ground selection lines GSLa and GSLb through pass transistors GPTa and GPTb.

The pass transistors GPTa, GPTb, PT1, . . . , PTn, SSPT1, SSPT2, and SSPT3 may be formed to electrically connect the ground selection lines GSLa and GSLb, the word lines WL1 to WLn, and the string selection lines SSL1, SSL2, and SSL3 to corresponding driving lines SS1, . . . , SS3, S1, . . . , Sn, GSa, and GSb in response to the high voltage signal VPP applied through the block word line BLKWL. The pass transistors GPTa, GPTb, PT1, . . . , PTn, SSPT1, SSPT2, and SSPT3 may be formed of high voltage transistors that can withstand high voltage.

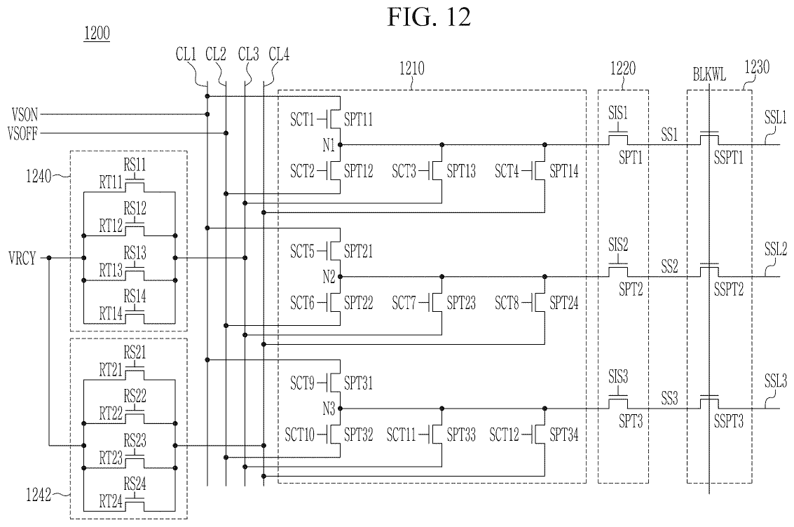

FIG. 12 is a block diagram of a part of a non-volatile memory device according to some example embodiments.

FIG. 12 illustrates that the address decoder 220 of the constituent elements of the non-volatile memory device of FIG. 2 includes recovery drivers 1240 and 1242, but the recovery drivers 1240 and 1242 may be included in the voltage generator 260.

Referring to FIG. 12, an address decoder 1200 may include a voltage transmission circuit 1210, a selection switch circuit 1220, a pass switch circuit 1230, and recovery drivers 1240 and 1242. The voltage transmission circuit 1210, the selection switch circuit 1220, and the recovery drivers 1240 and 1242 may form the string selection driver 1112 of FIG. 11.

The pass switch circuit 1230 may include pass transistors SSPT1, SSPT2, and SSPT3. The pass transistors SSPT1, SSPT2, and SSPT3 may connect the string selection lines SSL1, SSL2, and SSL3 and the driving lines SS1, SS2, and SS3, respectively. Gates of the pass transistors SSPT1, SSPT2, and SSPT3 may be commonly connected to the block word line BLKWL, and may connect the string selection lines SSL1, SSL2, and SSL3 to the driving lines SS1, SS2, and SS3, respectively in response to the high voltage applied through the block word line BLKWL.

The selection switch circuit 1220 may include selection transistors SPT1, SPT2, and SPT3 connected to the voltage transmission circuit 1210 and pass transistors SSPT1, SSPT2, and SSPT3, respectively. Each of the selection transistors SPT1, SPT2, and SPT3 is selectively turned on responding to driving line selection signals SIS1, SIS2, and SIS3 applied to the gates, and may provide voltages transmitted from the voltage transmission circuit 1210 to at least a part of the driving lines SS1, SS2, and SS3. The selection transistors SPT1, SPT2, and SPT3 may be connected between nodes N1, N2, and N3 and the driving lines SS1, SS2, and SS3.

The driving line selection signals SIS1, SIS2, and SIS3 may be included in the switching control signals SCS of FIG. 9.

The voltage transmission circuit 1210 may include a plurality of transistors SPT11, SPT21, and SPT31 between a connection line CL1 and the respective nodes N1, N2, and N3, a plurality of transistors SPT12, SPT22, and SPT32 connected between a connection line CL2 and the respective nodes N1, N2, and N3, a plurality of transistors SPT13, SPT21, and SPT33 connected between a connection line CL3 and the respective nodes N1, N2, and N3, and a plurality of transistors SPT14, SPT24, and SPT34 connected between a connection line CL4 and the respective nodes N1, N2, and N3.

The plurality of transistors SPT11, SPT21, and SPT31 may include gates respectively receiving a plurality of selection signals SCT1, SCT5, and SCT9. The plurality of transistors SPT12, SPT22, and SPT32 may include gates respectively receiving a plurality of selection signals SCT2, SCT6, and SCT10. The plurality of transistors SPT13, SPT23, and SPT33 may include gates respectively receiving a plurality of selection signals SCT3, SCT7, and SCT11. The plurality of transistors SPT14, SPT24, and SPT34 may include gates respectively receiving a plurality of selection signals SCT4, SCT8, and SCT12.

The plurality of selection signals SCT1 to SCT12 may be included in the switching control signals SCS of FIG. 9.

The connection line CL1 may be applied with the string selection turn-on voltage VSON, and the connection line CL2 may be applied with the string selection turn-off voltage VSOFF. The recovery voltage VRCY may be applied to the connection line CL3 through a recovery driver 1240, and the recovery voltage VRCY may be applied to the connection line CL4 through a recovery driver 1242.

The plurality of transistors SPT11, SPT21, and SPT31 may be turned on responding to the plurality of selection signals SCT1, SCT6, and SCT9 and may provide the string selection turn-on voltage VSON transmitted to the connection line CL1 to the driving lines SS1, SS2, and SS3 through the selection transistors SPT1, SPT2, and SPT3, and the plurality of transistors SPT12, SPT22, and SPT32 may be turned on responding to the plurality of selection signals SCT2, SCT6, and SCT10 and may provide the string selection turn-off voltage VSOFF transmitted to the connection line CL2 to the driving lines SS1, SS2, and SS3 through the selection transistors SPT1, SPT2, and SPT3. The plurality of transistors SPT13, SPT23, and SPT33 may be turned on responding to the plurality of selection signals SCT3, SCT7, and SCT11, and may provide the recovery voltage VRCY transmitted to the connection line CL3 to the driving lines SS1, SS2, and SS3 through the selection transistors SPT1, SPT2, and SPT3. The plurality of transistors SPT14, SPT24, and SPT34 may be turned on responding to the plurality of selection signals SCT4, SCT8, and SCT12, and may provide the recovery voltage VRCY transmitted to the connection line CL4 to the driving lines SS1, SS2, and SS3 through the selection transistors SPT1, SPT2, and SPT3.

The recovery driver 1240 may apply the recovery voltage VRCY to the connection line CL3 with a different drive strength. The recovery driver 1242 may apply the recovery voltage VRCY to the connection line CL4 with a different drive strength.

Each of the recovery drivers 1240 and 1242 may include a plurality of transistors RT11 to RT14 or RT21 to RT24. The plurality of transistors RT11 to RT14 may include gates connected between a recovery voltage generator (for example, the recovery voltage generator 1030 of FIG. 100) and the connection line CL3 and receiving driving signals RS11 to RS14, respectively. The plurality of transistors RT21 to RT24 may include gates connected between the recovery voltage generator 1030 and the connection line CL4 and receiving driving signals RS21 to RS24, respectively.

The plurality of transistors RT11 to RT14 may be turned on in response to the driving signals RS11 to RS14. As the number of the plurality of transistors RT11 to RT14 turned on increases, drive strength for transferring the recovery voltage VRCY to the connection line CL3 may increase. The plurality of transistors RT21 to RT24 may be turned on in response to driving signals RS21 to RS24. As the number of the plurality of transistors RT21 to RT24 turned on increases, drive strength for transferring the recovery voltage VRCY to the connection line CL4 may increase.

In some example embodiments, the number of turned-on plurality of transistors RT11 to RT14 and the number of turned-on plurality of transistors RT21 to RT24 may be different in the recovery period. That is, in the recovery section, the intensity of the recovery voltage VRCY applied to the string selection lines SSL1 and SSL3 electrically connected to the connection line CL3 and the intensity of the recovery voltage VRCY applied to the string selection line SSL2 electrically connected to the connection line CL4 may be different from each other

The switching control signals SCS of FIG. 9 may include the drive signals RS11, . . . , RS14, RS21, . . . , and RS24.

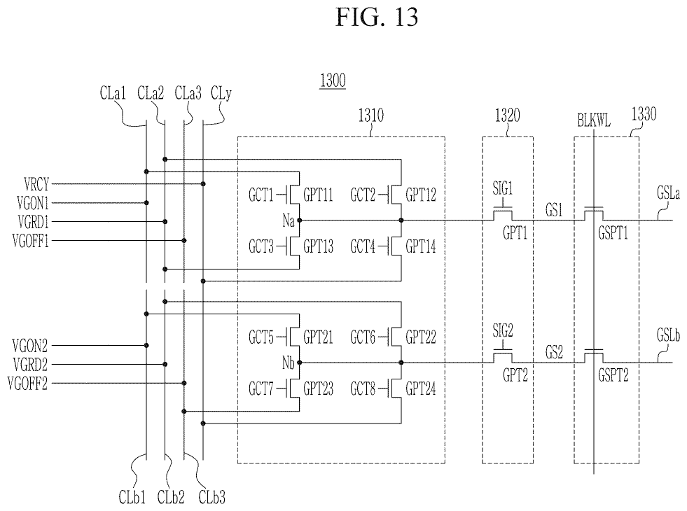

FIG. 13 is a block diagram of a part of a non-volatile memory device according to some example embodiments.

Referring to FIG. 13, an address decoder 1200 may include a voltage transmission circuit 1310, a selection switch circuit 1320, and a pass switch circuit 1330. The voltage transmission circuit 1310 and the selection switch circuit 1320 may form the ground selection driver 1114 of FIG. 11.

The pass switch circuit 1330 may include pass transistors GSPT1 and GSPT2. The pass transistors GSPT1 and GSPT2 may connect ground selection lines GSLa and GSLb and driving lines GS1 and GS2, respectively. Gates of the pass transistors GSPT1 and GSPT2 are commonly connected to a block word line BLKWL, and in response to a high voltage applied through the block word line BLKWL, the ground selection lines GSLa and GSLb may be connected to each of the driving lines GS1 and GS2 respectively.

The selection switch circuit 1320 may include selection transistors GPT1 and GPT2 connected to the voltage transmission circuit 1310 and the pass transistors GSPT1 and GSPT2, respectively. Each of the selection transistors GPT1 and GPT2 may be selectively turned on in response to the driving line selection signals SIG1 and SIG2 applied to the gate, and may provide voltages transmitted from the voltage transmission circuit 1310 to at least some of the driving lines GS1 and GS2. The selection transistors GPT1 and GPT2 may be connected between nodes Na and Nb and the driving lines GS1 and GS2.

The driving line selection signals SIG1 and SIG2 may be included in the switching control signals SCS of FIG. 9.

The voltage transmission circuit 1310 may include a transistor GPT11 connected between a connection line CLa1 and the node Na, a transistor GPT12 connected between a connection line CLa2 and the node Na, a GPT13 connected between a connection line CLa3 and the node Na, a transistor GPT14 connected between a connection line CLy and the node Na, a transistor GPT21 connected between a connection line CLb1 and the node Nb, a transistor GPT22 connected between a connection line CLb2 and the node Nb, a transistor GPT23 connected between a connection line CLb3 and the node Nb, and transistor GPT24 connected between the connection line CLy and the node Nb.

The transistor GPT11 may include a gate receiving a selection signal GCT1. The transistor GPT12 may include a gate receiving a selection signal GCT2. The transistor GPT13 may include a gate receiving a selection signal GCT3. The transistor GPT14 may include a gate receiving a selection signal GCT4. The transistor GPT21 may include a gate receiving a selection signal GCT5. The transistor GPT22 may include a gate receiving a selection signal GCT6. The transistor GPT23 may include a gate receiving a selection signal GCT7. The transistor GPT24 may include a gate receiving a selection signal GCT8.

The plurality of selection signals GCT1 to GCT8 may be included in the switching control signals SCS of FIG. 9.

A ground selection turn-on voltage VGON1 may be applied to the connection line CLa1, a ground selection read voltage VGRD1 may be applied to the connection line CLa2, and a ground selection turn-off voltage VGOFF1 may be applied to the connection line CLa3. A ground selection turn-on voltage VGON2 may be applied to the connection line CLb1, a ground selection read voltage VGRD2 may be applied to the connection line CLb2, and a ground selection turn-off voltage VGOFF2 may be applied to the connection line CLb3. The recovery voltage VRCY may be applied to the connection line CLy. Hereinafter, it is assumed that the ground selection turn-on voltage VGON1 and the ground selection turn-on voltage VGON2 are substantially the same or the same, the ground selection read voltage VGRD1 and the ground selection read voltage VGRD2 are substantially the same or the same, the ground selection turn-off voltage VGOFF1 and the ground selection turn-off voltage VGOFF2 are substantially the same or the same, the ground selection turn-on voltage VGON1 is greater than the ground selection read voltage VGRD1, and the ground selection read voltage VGRD1 is greater than the ground selection turn-off voltage VGOFF1.

The transistor GPT11 may be turned on responding to the selection signal GCT1 and provide the ground selection turn-on voltage VGON1 transmitted to the connection line CLa1 to the driving line GS1 through the selection transistor GPT1, the transistor GPT12 may be turned on responding to the selection signal GCT2 and provide the ground selection read voltage VGRD1 transmitted to the connection line CLa2 to the driving line GS1 through the selection transistor GPT1, and the transistor GPT13 may be turned on responding to the selection signal GCT3 and provide the ground selection turn-off voltage VGOFF1 transmitted to the connection line CLa3 to the selection transistor GPT1. The transistor GPT21 may be turned on responding to the selection signal GCT5 and provide the ground selection turn-on voltage VGON2 transmitted to the connection line CLb1 to the driving line GS2 through the selection transistor GPT2, the transistor GPT22 is turned on responding to the selection signal GCT6 and provide the ground selection read voltage VGRD2 transmitted to the connection line CLb2 to the driving line GS2 through the selection transistor GPT2, and the transistor GPT24 is turned on responding to the selection signal GCT8 and provide ground selection turn-off voltage VGOFF2 transmitted to the connection line CLb3 to the driving line GS2 through the selection transistor GPT2. The plurality of transistors GPT14 and GPT24 are turned on responding to the plurality of selection signals GCT4 and GCT8, and provides the recovery voltage VRCY transmitted to the connection line CLy to the driving lines GS1 and GS2 through the selection transistors GPT1 and GPT2.

The switching control signals SCS of FIG. 9 may include the driving signals GCT1 to GCT8.

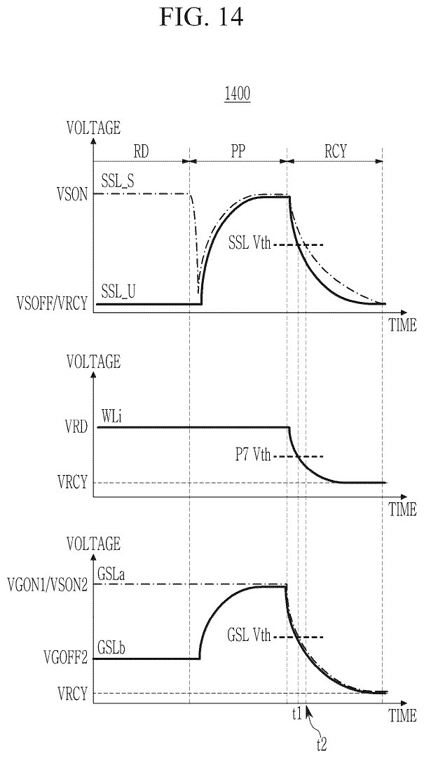

FIG. 14 shows voltages of a string selection line, a word line, and a ground selection line in the recovery period after read.

In FIG. 14, it will be described that a string selection line SSL_S is the string selection line SSL2 of FIG. 12, and unselected string selection lines SSL_U are string selection lines SSL1 and SSL2 of FIG. 12.

Referring to FIG. 14, during a read period RD, the string selection turn-on voltage VSON may be applied to the string selection line SSL_S, and the string selection turn-off voltage VSOFF may be applied to the unselected string selection line SSL_U. That is, during the read period RD, the selected string selection transistor driven by the select string selection line SSL_S is turned on and the unselected string selection transistor driven by the unselected string selection line SSL_U is turned off.

During the read period RD, a read voltage VRD is applied to a selection word line WLi. The read voltage VRD has a voltage level to determine a threshold voltage level of a selected memory cell.

During the read period RD, the ground selection turn-on voltage VGON1 is applied to the ground selection line GSLa and the ground selection turn-off voltage VGOFF2 is applied to the ground selection line GSLb. The cell string can be selected by appropriately applying the ground selection turn-on voltage VGON1 and the ground selection turn-off voltage VGOFF2 to the ground selection line GSLa and the ground selection line GSLb during the read period RD, based on the difference between the threshold voltage per cell string CS1, CS2, CS3 of the selected ground selection transistor driven by the ground selection line GSLa and the threshold voltage per cell string CS1, CS2, CS3 of the selected ground selection transistor driven by the ground selection line GSLb.

During a post pulse period PP, the string selection turn-on voltage VSON may be applied to the unselected string selection line SSL_U. In some example embodiments, at the timing when the post pulse period PP is initiated, the unselected string selection line SSL_U may be connected to connection line CL1. As the unselected string selection line SSL_U to which the ground selection turn-off voltage (VSOFF) is applied is connected to the connection line CL1, the voltage of the string selection line SSL_U connected to the connection line CL1 may be lowered.

During the post pulse period PP, the ground selection turn-on voltage VGON2 may be applied to the ground selection line GSLb.

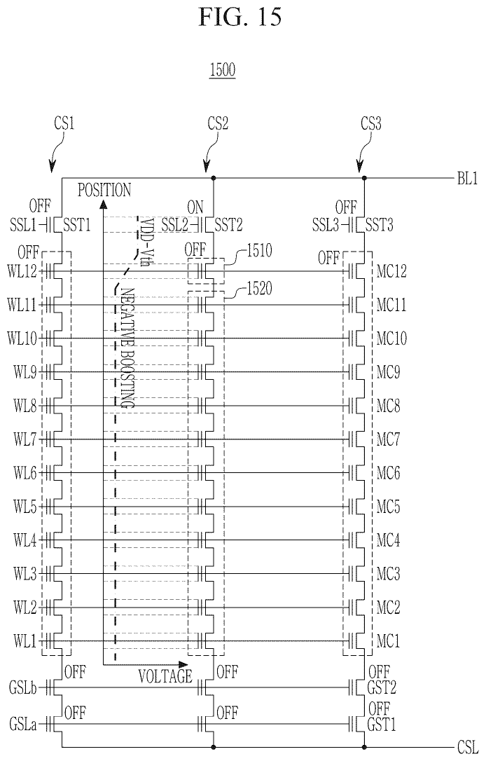

During a recovery period RCY, the recovery voltage VRCY may be applied to the string selection line SSL_S, the unselected string selection line SSL_U, the selection word line WLi, the ground selection line GSLa, and the ground selection line GSLb. Due to the RC deviation of the string selection lines SSL1, SSL2, and SSL3, the string selection line SSL_U may reach a threshold voltage SSL Vth of the string selection line at t1, and the string selection line SSL_S may reach the threshold voltage SSL Vth of the string selection line at t2. It is assumed that selection word line WLi, the ground selection line GSLa, and the ground selection line GSLb all reach threshold voltages P7 Vth and GSL Vth of each line at t1. Voltage potential of the cell string between t1 and t2 will be described with reference to FIG. 15.

FIG. 15 is a voltage potential graph of cell strings according to the voltages of FIG. 14.

The program operation may proceed sequentially from the lower word line. That is, since the program operation is sequentially performed from the word line WL1 to the word line WL12, when the word line WL12 is a selected word line for the program operation, program operation for word lines WL1 to WL11 may be completed.

Referring to FIG. 15, after t1, voltages of the word lines WL1 to WL12 may be lower than threshold voltages of memory cells MC1 to MC12 by the recovery voltage VRCY. A voltage of a channel corresponding to the memory cells MC1 to MC12 may become a ground voltage GND (e.g., 0V) by the recovery voltage VRCY. In addition, the voltages of the ground selection lines GSLa and GSLb may also be discharged to the recovery voltage VRCY.

When the non-volatile memory device performs the recovery operation, the voltage of word lines WL1 to WL12 may be discharged from the read voltage (or verify voltage) to the recovery voltage VRCY. Accordingly, the charges of the word lines WL1 to WL12 may be negatively down-coupled, which is called negative boosting or under-coupling. As a result, the voltage of the section of the word lines WL1 to WL11 may become a negative voltage by negative boosting. Since the string selection transistor SST is turned on, the power supply voltage VDD may be applied to the memory cell MC12 connected to the word line WL12. Accordingly, a voltage of a channel corresponding to the memory cell MC12 may be a difference between the power supply voltage and the threshold voltage (VDD−Vth).

Accordingly, a voltage level difference may occur between channels corresponding to the memory cells MC1 to MC11 and a channel corresponding to the memory cell MC12. That is, a memory cell in an erased state may be programmed in lower word lines MC1 to MC11 by band to band tunneling (BTBT) or HCI. That is, program and read disturbance may be induced. As the read voltage increases and the program and read counts are repeated, such program and read disturbances may occur.

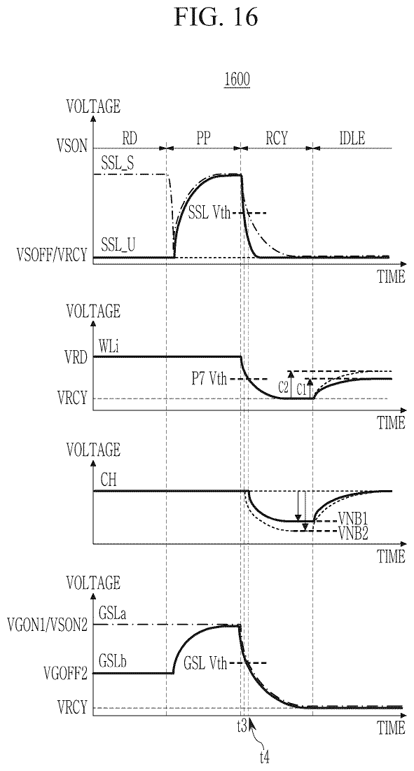

FIG. 16 shows voltages of the string selection line, the word line, the channel, and the ground selection line in the recovery operation.

In FIG. 16, it is described that the string selection line SSL_S is the string selection lines SSL1 and SSL2 of FIG. 12, and the unselected string selection line SSL_U is the string selection line SSL2 of FIG. 12.

Referring to FIG. 16, during the recovery period RCY, the recovery voltage VRCY may be applied to the string selection line SSL_S, the unselected string selection line SSL_U, the selection word line WLi, the ground selection line GSLa, and the ground selection line GSLb. Due to the RC deviation of the string selection lines SSL1, SSL2, and SSL3, the string selection line SSL_U may reach the threshold voltage SSL Vth of the string selection line at t3, and the string selection line SSL_S may reach the threshold voltage SSL Vth of the string selection line at t4. It is assumed that the selection word line WLi, the ground selection line GSLa, and the ground selection line GSLb all reach the threshold voltages P7 Vth and GSL Vth of each line at t4.

Referring to FIG. 15 together, in the cell strings CS1 and CS3, the string selection transistors SST1 and SST3 are turned off at t3 and thus the memory cells (MC1 to MC12 and the ground selection transistors GST1 and GST2 connected to the cell strings CS1 and CS3 are in a floated state, and the voltages of the word lines WL1 to WL12 connected to the memory cells MC1 to MC12 are discharged by the recovery voltage VRCY, and therefore the channel voltages of memory cells MC1 to MC12 start to fall from t3 before t4 at which the channels of memory cells MC1 to MC12 are turned off by the recovery voltage VRCY. In contrast, in the cell string CS2, the string selection transistor SST2 is turned off at t4, and the channel voltages of memory cells MC1 to MC12 start to fall. Therefore, when the recovery period RCY ends, the voltage of the channel CH of the cell strings S1 and CS3 may be a second negative voltage VNB2, and the voltage of the channel CH of the cell string CS2 may be a first negative voltage VNB1 higher than the second negative voltage VNB2. Then, in an idle period IDLE, when the voltage of the channel CH of each of the cell strings CS1, CS2, and CS3 increases due to a leakage current component of the string selection transistors SST1, SST2, and SST3, the voltage of the word line WLi of the cell strings CS1 and CS3 may rise by a second size C2 corresponding to the second negative voltage VNB2, and the voltage of the word line WLi of the cell string CS2 may rise by a first size C1 corresponding to the first negative voltage VNB1. Therefore, the voltage of the word line WLi of the cell strings CS1 and CS3 rises above the threshold voltage P7 Vth, and the memory cell connected to the word line WLi can be programmed. That is, program and read disturbance may be induced.

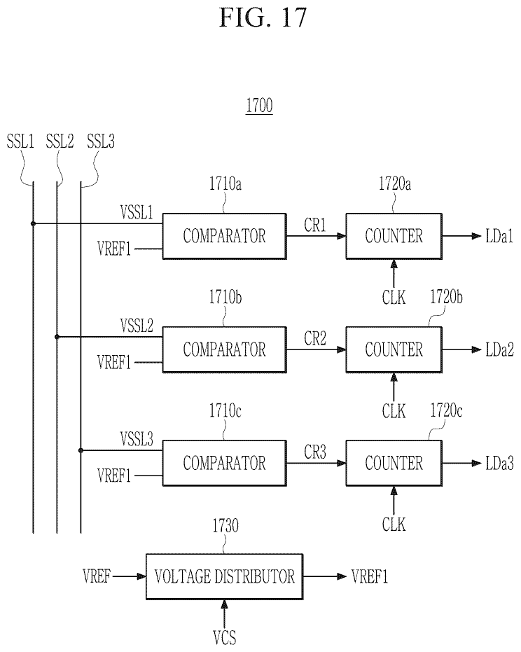

FIG. 17 is a block diagram of a voltage detector according to some example embodiments.

Referring to FIG. 17, a voltage detector 1700 may include a plurality of comparators 1710a, 1710b, and 1710c, a plurality of counters 1720a, 1720b, and 1720c, and a voltage distributor 1730.

The plurality of comparators 1710a, 1710b, and 1710c may be connected to the plurality of string selection lines SSL1, SSL2, and SSL3. The plurality of comparators 1710a, 1710b, and 1710c may compare voltages VSSL1, VSSL2, and VSSL3 and a first reference voltages VREF1 of the plurality of string selection lines SSL1, SSL2, and SSL3, and may output comparison result signals CR1, CR2, and CR3 of the voltages VSSL1, VSSL2, and VSSL3 and the first reference voltage VREF1.

The plurality of counters 1720a, 1720b, and 1720c may be connected to output terminals of the plurality of comparators 1710a, 1710b, and 1710c. The plurality of counters 1720a, 1720b, and 1720c may be enabled based on the comparison result signals CR1, CR2, and CR3, and may output detection signals LDa1, LDa2, and LDa3 by counting the number of clocks of clock signal CLK during an enabled period.

The voltage distributor 1730 may receive the reference voltage VREF and the control signal VCS, and output the first reference voltage VREF1 obtained by converting the reference voltage VREF based on the control signal VCS.

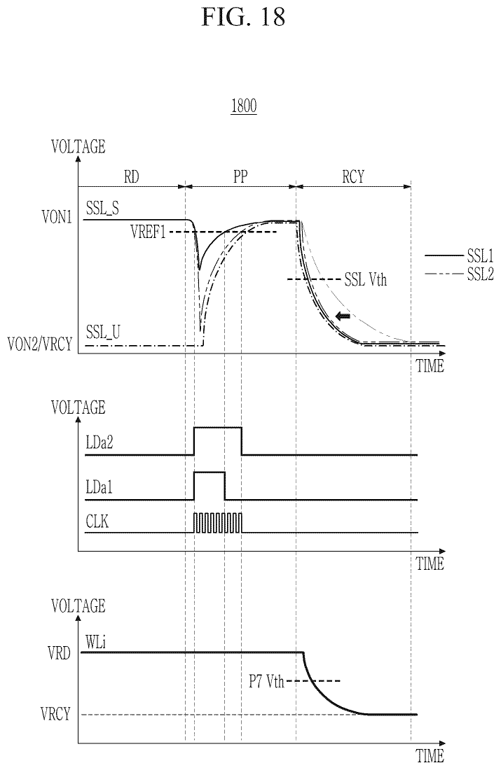

FIG. 18 shows the voltage change of the voltage detector signal, string selection line, and word line according to some example embodiments.

Referring to FIG. 18, when the string selection line SSL1 is the selected string selection line SSL_S, the voltage change of the selected string selection line SSL_S during a post pulse period PP may be smaller than the voltage change of the selected string selection line SSL_S during the post pulse period PP when the string selection line SSL_S is the selected string selection line SSL_S. That is, the string selection line SSL2 having a large RC value has a greater voltage change.

When the string selection line SSL1 is the selected string selection line SSL_S, a voltage detector (for example, the voltage detector 1700 in FIG. 17) may count the number of clock signals CLK and output a detection signal LDa1. A control circuit (for example, the control circuit 250 of FIG. 2) may generate a switching control signal SCS based on the detection signal LDa1. In some example embodiments, the control circuit 250 may generate driving signals RS11 to RS14 that controls a recovery driver (for example, the recovery driver 1240 of FIG. 12) such that the recovery voltage VRCY may be applied to the string selection line SSL1 as the drive strength corresponding to the detection signal LDa1. The control circuit 250 may determine the drive strength based on a period in which the detection signal LDa1 has an enable level. For example, the control circuit 250 may determine the drive strength when a period in which the detection signal LDa1 has the enable level has a first time length to be stronger than the drive strength when a period in which the detection signal LDa1 has the enable level is s second time length, which is shorter than the first time length. In some example embodiments, when the period during which the detection signal LDa1 has an enable level is less than a predetermined (or, alternatively, desired or determined) length of time, the control circuit 250 may determine a drive strength for applying the recovery voltage to the selected string selection line SSL_S and a drive strength for applying the recovery voltage to the unselected string selection line SSL_U to be substantially the same or the same. When the period during which the detection signal LDa1 has the enable level is equal to or longer than the predetermined (or, alternatively, desired or determined) length of time, the control circuit 250 may determine a drive strength for applying the recovery voltage to the selected string selection line SSL_S to be stronger than a drive strength for applying the recovery voltage to the unselected string selection line SSL_U. The control circuit 250 may determine the drive strength corresponding to a range including a period in which the detection signal LDa1 has an enable level among a plurality of time length ranges.

When the string selection line SSL2 is the selected string selection line SSL_S, the voltage detector 1700 may count the number of clock signals CLK and output a detection signal LDa2. The control circuit 250 may generate a switching control signal SCS based on the detection signal LDa2. In some example embodiments, the control circuit 250 may generate drive signals RS21 to RS24 that control the recovery driver 1242 to apply the recovery voltage VRCY to the string selection line SSL2 as the drive strength corresponding to the detection signal LDa2.

Since the RC value of the string selection line SSL2 is greater than the RC values of the string selection lines SSL1, and SSL3, the recovery voltage VRCY may be applied with a stronger drive strength. Therefore, assuming that the size (channel width W/channel length L) of the transistors RT11, . . . , RT14, RT21, . . . , and RT24 in the recovery drivers 1240 and 1242 are the same, the number of transistors of recovery driver 1242 turned on when string selection line SSL2 is the selected string selection line SSL_S may be greater than the number of transistors of the recovery driver 1240 turned on when the string selection line SSL1 is the selected string selection line SSL_S,

Therefore, all string selection transistors SST1, SST2, and SST3 may be turned off at substantially the same or the same timing by differently setting the drive strength for applying the recovery voltage VRCY to each of the string selection lines SSL1, SSL2, and SSL3 having different RC values. Accordingly, it is possible to prevent or reduce HCI phenomenon and read disturb degradation due to the RC deviation of the string selection lines SSL1, SSL2, and SSL3. As described above, there may be an effect of improving memory performance of the non-volatile memory device 200. Alternatively, or additionally, as described above, because performance of the non-volatile memory device 200 has been improved, there may be an effect of improving the non-volatile memory device 200 and memory performance, and thus device performance, improved power consumption by improving power utilization, and the like.

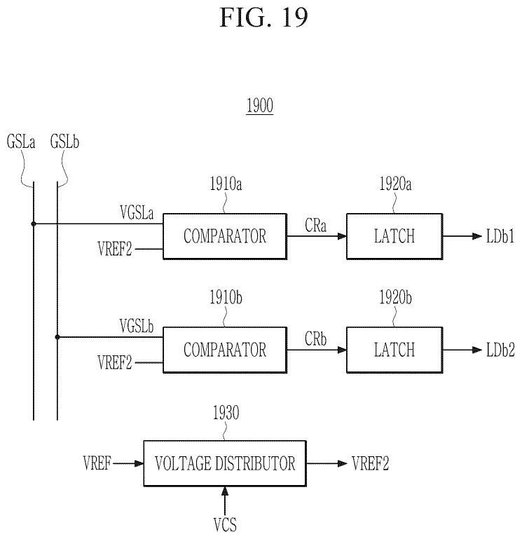

FIG. 19 is a block diagram of a voltage detector according to some example embodiments.

Referring to FIG. 19, a voltage detector 1900 may include a plurality of comparators 1910a and 1910b, a plurality of latches 1920a and 1920b, and a voltage distributor 1930.

The plurality of comparators 1910a and 1910b may be connected to a plurality of ground selection lines GSL1 and GSL2. The plurality of comparators 1910a and 1910b compares the voltages VGSLa and VGSLb of the plurality of ground selection lines GSL1 and GSL2 and the second reference voltage VREF2, and may output comparison result signals CRa and CRb of the voltages VGSLa and VGSLb and the second reference voltage VREF2.

The plurality of latches 1920a and 1920b may be connected to output terminals of the plurality of comparators 1910a and 1910b. The plurality of latches 1920a and 1920b may output detection signals LDb1 and LDb2 of which levels are transitioned by the comparison result signals CRa and CRb.

The voltage distributor 1930 may receive the reference voltage VREF and the control signal VCS, and output the second reference voltage VREF2 obtained by converting the reference voltage VREF based on the control signal VCS.

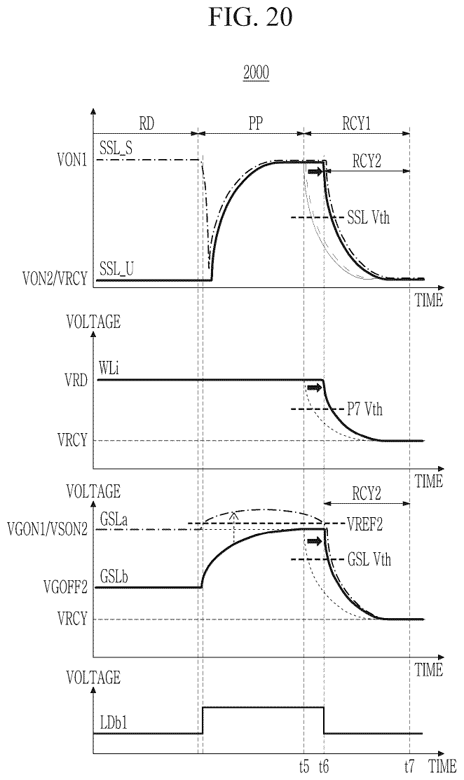

FIG. 20 shows the voltage change of the voltage detector signal, string selection line, word line, and ground selection line according to some example embodiments.

Referring to FIG. 20, during the post pulse period PP, the ground selection turn-on voltage VGON1 may be applied to the ground selection line GSLa and the ground selection turn-on voltage VGON2 may be applied to the ground selection line GSLb. As the voltage of the ground selection line GSLb increases, the voltage of the ground selection line GSLa, which is capacitively coupled with the ground selection line GSLb, may be boosted together. At t5, a recovery period RCY1 starts, and the recovery voltage VRCY may be applied to the ground selection lines GSLa and GSLb. Discharging may begin at a voltage higher than that of the ground selection line GSLb at the ground selection line GSLa. Therefore, timing at which the ground selection transistors GST1, GST2, and GST3 are turned off may be different for each of the cell strings CS1, CS2, and CS3. Accordingly, HCI phenomenon and read disturb degradation may occur in the cell string.

The voltage detector 1900 may detect the voltage of the ground selection line GSLa and output a detection signal LDb1. The voltage detector 1900 may compare the voltage of the ground selection line GSLa with the second reference voltage VREF2, and output the detection signal LDb1 of which the level is transitioned when the voltage of the ground selection line GSLa is substantially equal or equal to the second reference voltage VREF2. In some example embodiments, the second reference voltage VREF2 may be a voltage greater than the ground selected turn-on voltage (VGON1/VGON2) and the ground selected turn-off voltage (VGOFF1/VGOFF2).

The control circuit (for example, the control circuit 250 of FIG. 2) may provide a switching control signal SCS based on a falling edge of the detection signal LDb1. The control circuit 250 may output the switching control signal SCS that controls an address decoder to apply the recovery voltage VRCY to the plurality of string selection lines SSLs, the plurality of word lines WLs, and the plurality of ground selection line GSLs at a timing corresponding to the falling edge of the detection signal LDb1.

In some example embodiments, the control circuit 250 may generate drive line selection signals SIG1 and SIG2 that control a selection switch circuit (for example, the selection switch circuit 1320 of FIG. 13) to apply the recovery voltage VRCY to the ground selection lines GSLa and GSLb at a timing corresponding to the falling edge of detection signal LDb1.

In some example embodiments, the control circuit 250 may generate driving line selection signals SIS1, SIS2, and SIS3 that control a selection switch circuit (for example, the selection switch circuit 1220 of FIG. 12) to apply the recovery voltage VRCY to the string selection lines SSL1, SSL2, and SSL3 at a timing corresponding to the falling edge of detection signal LDb1.

In some example embodiments, the control circuit 250 may output the switching control signal SCS that controls a word line driver (for example, the word line driver 1113 of FIG. 11) to apply the recovery voltage VRCY to the word lines WL1 to WLn at a timing corresponding to the falling edge of detection signal LDb1.

Therefore, all ground selection transistors GST1 and GST2 may be turned off at substantially the same or the same timing. Accordingly, although voltage boosting occurs between the ground selection lines GSLa and GSLb coupled by capacitive coupling, the HCI phenomenon and read disturb degradation can be prevented or reduced. As described above, there may be an effect of improving memory performance of the non-volatile memory device 200. Alternatively, or additionally, as described above, because performance of the non-volatile memory device 200 has been improved, there may be an effect of improving the non-volatile memory device 200 and memory performance, and thus device performance, improved power consumption by improving power utilization, and the like.

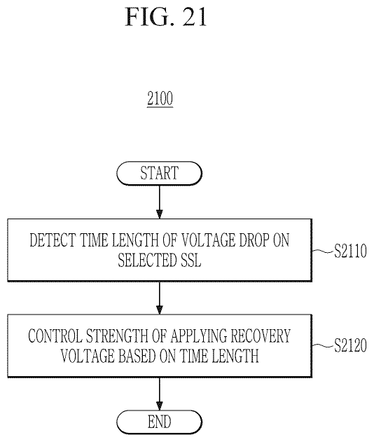

FIG. 21 is a flowchart of a recovery method according to some example embodiments.

A non-volatile memory device (for example, the non-volatile memory device 120 of FIG. 1) detects a voltage drop period of the selected string selection line (S2110). The non-volatile memory device 120 may detect the voltage of the selected string selection line in the post pulse period before the recovery voltage is applied. The non-volatile memory device 120 may compare the voltage of the selected string selection line with the first reference voltage, and measure the length of time during which the voltage of the selected string selection line is less than or equal to the first reference voltage.

The non-volatile memory device 120 controls drive strength for applying a recovery voltage to the selected string selection line based on the voltage drop period (S2120). The non-volatile memory device 120 may differently set the intensity of the drive strength for applying the recovery voltage to the selected string selection line according to the length of the voltage drop period. For example, the non-volatile memory device 120 may set the intensity of the drive strength for applying a recovery voltage to the selected string selection line with a voltage drop period of the first time length to be larger than the intensity of the drive strength for applying a recovery voltage to the selected string selection line with a voltage drop period shorter than the first time length, which is a second time length.

According to some example embodiments, it is possible to prevent or reduce HCI phenomena in the cell string connected to a string selection line having a relatively slow voltage change and prevent or reduce read disturb degradation in the cell string connected to a string selection line having a relatively faster voltage change by applying a recovery voltage with a larger drive strength to the cell string connected to the string selection line having the relatively slower voltage change.

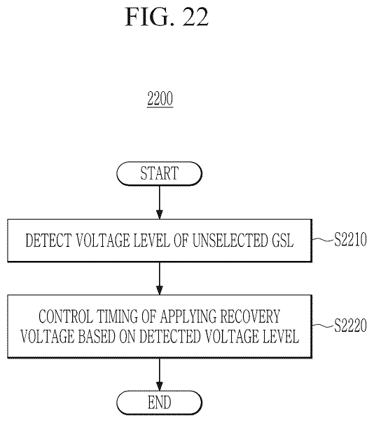

FIG. 22 is a flowchart of a recovery method according to some example embodiments.

A non-volatile memory device (for example, the non-volatile memory device 120 of FIG. 1) detects the voltage of the unselected ground selection line (S2210). The non-volatile memory device 120 may detect the voltage of the unselected string selection line in the post pulse period before the recovery voltage is applied. The non-volatile memory device 120 may compare the voltage of the unselected string selection line with the second reference voltage, and detect a timing when the voltage of the unselected string selection line is substantially equal or equal to the second reference voltage.

The non-volatile memory device 120 controls the timing of applying the recovery voltage to the ground selection line based on the detected voltage (S2220). The non-volatile memory device 120 may apply the recovery voltage to all ground selection lines at a time when the voltage of the unselected ground selection line becomes substantially equal or equal to the second reference voltage. In some example embodiments, the non-volatile memory device 120 may apply the recovery voltage to all string selection lines at a timing at which the voltage of the unselected ground selection line becomes substantially equal or equal to the second reference voltage. In some example embodiments, the non-volatile memory device 120 may apply the recovery voltage to all word lines at the timing at which the voltage of the unselected ground selection line is substantially equal or equal to the second reference voltage.

According to some example embodiments, when a voltage of a voltage-boosted ground selection line falls and reaches a predetermined (or, alternatively, desired or determined) voltage, the recovery voltage is applied, and thus the HCI phenomenon and read disturb degradation that may occur in not only the ground selection transistor but also the string selection transistor and memory cell can be prevented or reduced.

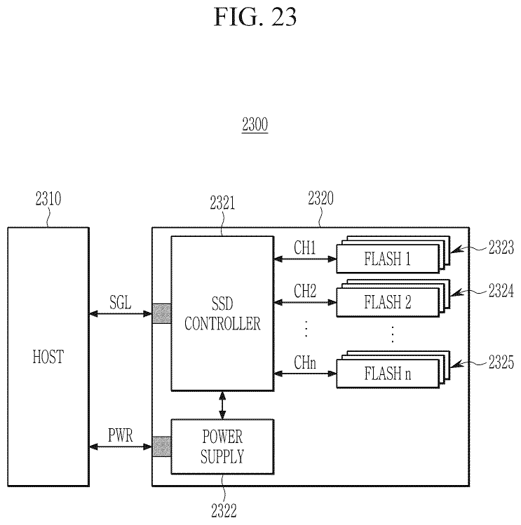

FIG. 23 is a block diagram of an example of application of the non-volatile memory device according to some example embodiments to a solid-state drive (SSD) system.

Referring to FIG. 23, an SSD system 2300 may include a host 2310 and an SSD 2320.

The SSD 2320 may be implemented with some of the example embodiments described with reference to FIG. 1 to FIG. 22. The SSD 2320 may exchange signals with the host 2310 through a signal connector SGL and receive power through a power connector PWR.

The SSD 2320 may receive a firmware image download command and a firmware image to be downloaded through the signal connector SGL.

The SSD 2320 may include a controller 2321, an auxiliary power supply 2322, and a plurality of memory systems 2323, 2324, and 2325. Each of the plurality of memory systems 2323, 2324, and 2325 may include one or more flash memory devices as storage devices. In addition, each flash memory device may include one or more die DIE, and one or more blocks may be disposed in each die DIE.

The flash memory device may detect a voltage drop period of a string selection line connected to a cell string included in one or more blocks, and apply a recovery voltage to the string selection line with a drive strength corresponding to the voltage drop period. In addition, the flash memory device may detect a voltage of a ground selection line connected to a cell string included in one or more blocks, and apply a recovery voltage to the ground selection line at a timing when the detected voltage reaches a predetermined (or, alternatively, desired or determined) voltage.

The controller 2321 may communicate with the plurality of memory systems 2323, 2324, and 2325 through a plurality of channels Ch1 to Chn.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure, or with timing, it is intended that precision of the time is not required but that the general timing is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

Although some example embodiments have been described in detail above, the scope of the present inventions are not limited thereto, and various modifications of a person of an ordinary skill in the art using the basic concepts of the present inventions defined in the following claims range and improved forms also fall within the scope of the present inventions.

What is claimed is:

1. A non-volatile memory device comprising:
a memory block including
a plurality of cell strings including
a plurality of string selection transistors and
a plurality of memory cells,
a first string selection line connected to a string selection transistor of a first cell string of the plurality of cell strings, and
a second string selection line connected to a string selection transistor of a second cell string of the plurality of cell strings; and
a control circuit configured to control a recovery operation to apply a recovery voltage with different driving strengths to the first string selection line and the second string selection line.

2. The non-volatile memory device of claim 1, wherein:
the first string selection line and the second string selection line have different RC values.

3. The non-volatile memory device of claim 1, wherein:
based on an RC value of the first string selection line being greater than an RC value of the second string selection line, the recovery operation is controlled to apply the recovery voltage to the first string selection line with a stronger drive strength than a drive strength for applying the recovery voltage to the second string selection line.

4. The non-volatile memory device of claim 1, further comprising a voltage detector configured to detect at least one voltage among the first string selection line and the second string selection line,
wherein the control circuit is further configured to determine the drive strength based on the voltage detected by the voltage detector.

5. The non-volatile memory device of claim 4, further comprising a voltage generator configured to generate a string selection turn-on voltage, a string selection turn-off voltage, and the recovery voltage,
wherein the voltage detector is further configured to detect a voltage of a selected string selection line to which the string selection turn-on voltage is provided among the first string selection line and the second string selection line.

6. The non-volatile memory device of claim 5, wherein:
the voltage detector is further configured to output a detection signal that counts a time length of a period in which a voltage of the selected string selection line detected by the voltage detector is less than or equal to a reference voltage in a post pulse period during which the string selected turn-on voltage is provided to an unselected string selection line to which the string selected turn-off voltage is provided, and
the control circuit is further configured to determine the drive strength based on the detection signal.

7. The non-volatile memory device of claim 6, wherein:
The control circuit is further configured to determine a drive strength to be stronger in relation to a longer time length based on the detection signal.

8. The non-volatile memory device of claim 6, further comprising a temperature sensor configured to provide temperature information,
wherein the control circuit is further configured to determine the reference voltage based on the temperature information.

9. The non-volatile memory device of claim 1, wherein:
the plurality of cell strings further comprise a plurality of ground selection transistors,
the memory block comprises a first ground selection line connected to a first ground selection transistors of the plurality of ground selection transistors and a second ground selection line connected to second ground selection transistors of the plurality of ground selection transistors, and
the control circuit is further configured to determine application timing of the recovery voltage to the first ground selection line and the second ground selection line based on a voltage of at least one of the first ground selection line and the second ground selection line.

10. The non-volatile memory device of claim 9, further comprising a voltage detector configured to detect a voltage of at least one of the first ground selection line and the second ground selection line,
wherein the control circuit is further configured to determine the timing in response to the voltage of the ground selection line, which has been boosted among the first ground selection line and the second ground selection line being a same voltage as a reference voltage, based on the voltage detected by the voltage detector.

11. The non-volatile memory device of claim 10, wherein:
the control circuit is further configured to determine an application timing of the recovery voltage to the first string selection line and the second string selection line based on a voltage of at least one of the first ground selection line and the second ground selection line.

12. The non-volatile memory device of claim 10, wherein:
the memory block further comprises a plurality of word lines connected to the plurality of memory cells, and
the control circuit is further configured to determine an application timing of the recovery voltage to the plurality of word lines based on a voltage of at least one of the first ground selection line and the second ground selection line.

13. A recovery method of a non-volatile memory device that includes a plurality of cell strings including a plurality of string selection transistors and a plurality of memory cells, comprising:
applying a string selection turn-on voltage to a first string selection line connected to a string selection transistor of a first cell string of the plurality of cell strings, and applying a string selection turn-off voltage to a second string selection line connected to a string selection transistor of a second cell string of the plurality of cell strings;
applying the string selection turn-on voltage to the first string selection line and the second string selection line;
counting a period of a voltage of the first string selection line being less than or equal to a first reference voltage; and
applying a recovery voltage with different drive strengths to the first string selection line and the second string selection line based on a time length of the period.

14. The recovery method of the non-volatile memory device of claim 13, wherein:
the applying the recovery voltage comprises
based on the time length of the period being longer than a time length, determining a first drive strength for applying the recovery voltage to the first string selection line to be greater than a second drive strength for applying the recovery voltage to the second string selection line, and
applying the recovery voltage with the first drive strength to the first string selection line and applying the recovery voltage with the second drive strength to the second string selection line.

15. The recovery method of the non-volatile memory device of claim 13, further comprising
receiving temperature information from a temperature sensor,
wherein the first reference voltage is determined based on the temperature information.

16. The recovery method of the non-volatile memory device of claim 13, wherein:
the plurality of cell strings further comprises a plurality of ground selection transistors, and
the recovery method of the non-volatile memory device further comprises:
applying a ground selection turn-on voltage to a first ground selection line connected to first ground selection transistors of the plurality of ground selection transistors and applying a ground selection turn-off voltage to a second ground selection line connected to second ground selection transistors of the plurality of ground selection transistors;
applying the ground selection turn-on voltage to the first ground selection line and the second ground selection line; and
applying the recovery voltage to the first ground selection line and the second ground selection line based on a voltage of the first ground selection line being a same voltage as a second reference voltage.

17. The recovery method of the non-volatile memory device of claim 16, wherein:
the applying the recovery voltage to the first ground selection line and the second ground selection line and the applying the recovery voltage with different drive strengths to the first string selection line and the second string selection line are performed when the voltage of the first ground selection line is same as the second reference voltage.

18. A semiconductor device comprising:
a substrate;
a stacking structure that includes a plurality of first selection gate electrodes and a plurality of memory gate electrodes stacked at a distance from each other on the substrate;
a first channel structure that penetrates the stacking structure and extends in a first direction;
an insulation pattern on the stacking structure and covers the first channel structure;
a conductive pattern that penetrates the insulation pattern and is connected with the first channel structure;
a plurality of second selection gate electrodes on the conductive pattern; and
a plurality of second channel structures that penetrate the plurality of second selection gate electrodes and extend in the first direction and thus widths of the plurality of second gate electrodes in a second direction that crosses the first direction are different from each other,
wherein the plurality of second selection gate electrodes are applied with a same voltage with different drive strengths.

19. The semiconductor device of claim 18, wherein:
a drive strength for applying a voltage to a second selection gate electrode with a smaller width in the second direction among the plurality of second selection gate electrodes is stronger than a drive strength for applying a voltage to a second selection gate electrode with a larger width in the second direction among the plurality of second selection gate electrodes.

20. The semiconductor device of claim 18, wherein:
an application timing of a voltage to the plurality of first selection gate electrodes is controlled based on a voltage of the first selection gate electrode of which the voltage is boosted among the plurality of first selection gate electrodes.
